(19) United States
(12) Patent Application Publication
(10) Pub. No.: US 2003/0126545 A1
(43) Pub. Date: Jul. 3, 2003

(54) Non-linear code-division multiple access technology with improved detection algorithms and error correction coding

(76) Inventor: Alfred Keng Tiong Tan, Hong Kong (HK)

Correspondence Address: SWIDLER BERLIN SHEREFF FRIEDMAN, LLP, 3000 K STREET, NW, BOX IP, WASHINGTON, DC, 20007, US

(21) Appl. No.: 09/970,995

(22) Filed: Oct. 5, 2001

(51) Int. Cl. H03M 13/03

(52) U.S. Cl. 714/786

(57) ABSTRACT

A method of channel spread signal coding is provided that enhances error correction coding schemes by further coding error correction coded signals based on a non-linear block error correction coding scheme that introduces a detectable pattern into the signal output prior to transmission. At the receiver end, the detectable pattern may be decorrelated enabling the use of RAKE receivers and enhanced decoding schemes.

### CROSS-REFERENCE TO PENDING APPLICATION

This application is related to co-pending U.S. patent application entitled “Method and Apparatus for Non-Linear Code-Division Multiple Access Technology” filed on Oct. 5, 2001.

### FIELD OF THE INVENTION

The present invention relates generally to coding and decoding algorithms for communication systems and, more particularly, to coding and decoding algorithms for code division multiple access (CDMA) systems that enhance conventional error correction coding schemes, robustness to noise and peak to average power properties of the transmitted signal. The technique also minimizes complexity within transmitting and receiving systems.

### BACKGROUND OF THE INVENTION

Recent advances in technology have given rise to communications electronics that are faster, consume less power and are less expensive as compared to those of earlier generations. This in turn has caused rapid growth in the global communications market, which includes both fixed and mobile segments. This rapid growth has manifested itself through increasing numbers of users of communication technologies, and the increasing services and bandwidth available to users. This growth is expected to continue for many years to come.

Current technologies for multi-user communication systems include code division multiple access (CDMA). In a widely used mobile cellular implementation of CDMA, up to 64 (or 256) signals are transmitted in parallel from a base station to mobile units. In realistic noise environments, this number is limited by the peak power that can be transmitted by law, or by the power control algorithms, which depend on the interference signals from other users. There is accordingly a necessary balance between the transmitted signal power of the composite CDMA signal and the number of parallel CDMA active users supported. Although a higher transmitted signal power will usually result in a better coverage and signal reception at the receivers, this will also result in higher interference in neighboring cells.

One performance indicator for mobile communication systems is the peak-to-average power (PAP) magnitude of the composite CDMA signals. High PAP has always been an inherent problem of CDMA systems. Pulse shaping and complex modulation techniques such as continuous phase modulation techniques have been developed to alleviate negative effects of high PAP. High PAP also makes a communications system more susceptible to non-linear distortions, which are usually introduced by high power non-linear amplifiers both in transmitters and receivers.

Problems persist in CDMA as indicated by the use of data channels devoted to pulse shaping and complex modulation techniques. These lower the bandwidth efficiency of the system. (Bandwidth efficiency is a measure on the ratio of bandwidth used for information transmission over the total amount of bandwidth used by the system.) Also, some CDMA systems require more expensive electronics, such as linear power amplifiers with high dynamic range, to handle signals with high PAP or encoding data channels. The alternative to this is to use non-linear power amplifiers, but these introduce non-linear distortions to the high PAP signals, possibly resulting in severe data corruption at the receiver.

A major problem with current third generation (3G) wireless communication systems is the limited user capacity for a given error performance when transmitting at very high data rates such as at 1 to 2 Megabits per second (Mbps) in the presence of interference from other users. This is primarily due to two factors. The first is the limited spreading factor in the standards. There is a spreading factor of 4 transmission chips when transmitting at 1 Mbps and a spreading factor of 2 transmission chips when transmitting at 2 Mbps using orthogonal variable spreading factor (OVSF) wide-band CDMA (WCDMA), which has a PAP of unity. The second factor is the sub-optimality of the coding used, given the interference environment. The option of multi-code CDMA (MC-CDMA) has high PAP and lack of robustness to interference and non-linear distortions.

Accordingly, there is a need to enhance the performance of CDMA to allow its operation in high-data rate, third-generation, wireless-communication systems. Any new system design should not only alleviate problems associated with high PAP, and improve robustness to interference, but achieve these improvements using a low-cost implementation in hardware, software or firmware within existing CDMA systems, or by a natural upgrade path.

### SUMMARY OF THE INVENTION

According to the present invention, a code division multiple access (CDMA) technology uses a class of non-linear block codes defined as Go-CDMA codes and matrices for signal coding. The result is coded signals that have robust noise immunity and good peak to average power (PAP) properties. In addition, algorithms for coding and decoding Go-CDMA coded signals exploit an inherent multinomial structure in the Go-CDMA coded sequences for improved signal detection.

According to another embodiment of the present invention, Go-CDMA schemes are proposed that enhance coding, including for example convolution, Turbo and block coding. These techniques may exploit enhanced Go-CDMA decoding techniques that take advantage of the multinomial structure of Go-CDMA coded signal. In the case of convolution coding, the new schemes combine the strength of convolution coding for error correction, and the signature recognition capabilities of the block Go-CDMA coding. The error correction capabilities of convolution coding together with Go-CDMA coding schemes according to an embodiment of the present invention are significantly greater than would be achieved by a simple concatenation of such codes.

Go-CDMA decoding may exploit the multinomial structure in the outcome of the majority logic encoding process of Go-CDMA coding. There is an associated or “built-in” parity error-correction coding bit extracted during decoding by virtue of the multinomial structure that may improve Go-CDMA decoding at marginal computational cost. This additional bit also may be exploited for improved decoding in a multi-stage coding and decoding scheme, and in particular when Go-CDMA is used in conjunction with convolution coding or Turbo coding, or block coding.

One preferred Go-CDMA scheme for wireless CDMA communication between the user and hub station includes in the transmitter coding scheme a concatenation of a convolution coder with a Go-CDMA coder. At the receiver side, the first decoding stage is a Go-CDMA soft decoder that recovers an extra bit, a parity bit, from the received Go-CDMA signal. The associated parity bit from the Go-CDMA soft decoding is then fed through and exploited in the second stage convolution decoding. This may be done via a Viterbi Algorithm and applied to “invert”, not the original convolution coding process, but an augmented coder, which also generates the parity bit in question. Effectively, according to this embodiment, the Go-CDMA stage serves to achieve the error correction capability of a higher rate convolution coder/decoder, although there is some signal energy loss.

The presence of the Go-CDMA stage allows signature recognition, which in turn permits the use of ‘RAKE symbol-detectable’ receiver architectures, not possible in purely convolution error-correction coding schemes. Other embodiments include the use of convolution coding together with more than one Go-CDMA coder and the use of Turbo coding or block coding with Go-CDMA coders, and the use of RAKE receivers.

Embodiments of the present invention have application in CDMA communication systems, giving improved performance on many measures over conventional CDMA and TDMA systems. These measures include, for example, peak-to-average power ratio (PAP), error correction as a function of l/n and n/α. Here l is the length of Go-CDMA coded sequence, n is the maximum number of multiple access channels and α is the current number of active access channels. The measures also include channel capacity in terms of message data rates, transmitted bit error rate as a function of signal-to-noise ratio (SNR), signal-to-interference ratio (SIR), where the interference is from neighboring cells, upper limits to the active-user numbers in a communication cell, and computational effort in coding and decoding. In comparison to prior art systems, the present invention exhibits significantly better error performance.

Embodiments of the present invention are well suited for implementation in any CDMA system. They are particularly well suited for high-bandwidth CDMA systems such as third generation and beyond CDMA systems. Moreover, in any CDMA system including a mobile communications unit, a base station, a transmitting station or receiving station that transmits parallel data message streams, Go-CDMA implementation may allow less signal shaping overhead and less expensive electronics to be implemented than conventional CDMA systems would allow.

A first embodiment of the present invention includes the application of Go-CDMA techniques with enhanced detection, as an augmentation to known convolution coding. Given a

$$\frac{m}{n}$$

rate convolution coder, where m is the number of input information bits and n is the number of output convolution coded bits, the Go-CDMA augmentation simply codes the n convolution code output bits, after interleaving, as l bits for transmission, using a n×l Go-CDMA code matrix. The decoding is the reverse process, namely first Go-CDMA decoding of the received signal using soft and enhanced detection, then the de-interleaving of the decoded signal. In the noise free case this recovers, in the channel, the n bits going into the Go-CDMA decoding and also an extra parity bit to give n+1 bits, and estimates these bits otherwise. These first stages of decoding are followed by a Viterbi decoder to “invert”, not the original convolution

$$\frac{m}{n}$$

coder, but an augmented

$$\frac{m}{n + 1}$$

coder which also generates the appropriate parity bit. This recovers the sequence of m bits from the sequence of n+1 bits, in the noise free case and achieves maximum likelihood estimates otherwise. The decoding process achieves, with some signal loss, equivalently a

$$\frac{m}{n + 1}$$

convolution coder/decoder. The latter is stronger than an optimum

$$\frac{m}{n}$$

rate convolution coder/decoder. Optimization of convolution codes for “best” performance makes sense, and is straightforward using standard techniques.

A second embodiment of the present invention includes two or more parallel convolution/Go-CDMA coding (of the above first embodiment) blocks are constructed together to form a Turbo coding structure where there is an interleaver between each pair of the parallel convolution/Go-CDMA coding blocks.

A third embodiment of the present invention includes a linear or non-linear block code, rather than a convolution code as above. A method for passing parity bits for error correction from the Go-CDMA stage of decoding to enhance the next stage of decoding is devised.

A fourth embodiment of the invention includes single or multistage decoding when the built-in parity bit of any Go-CDMA decoding block is not passed to the next stage, such as when the last stage is Go-CDMA decoding. In such cases the parity bit is used to enhance the detection at that particular stage when indicated, as in low noise environments. The enhanced detection is achieved by replacing the most likely bit with an error by one calculated using the other bits and the parity bit.

A fifth embodiment of the present invention is when the Go-CDMA coding stage (where a majority logic operation is performed) in the previous embodiments, is replaced by the use of Go-CDMA codes as orthogonal codes in a MC-CDMA architecture—an embodiment termed MC-Go-CDMA in the cross referenced patent. In this embodiment, the majority logic operation is performed on the received signal in the receiver, before Go-CDMA decoding, in order extract the extra parity bit for use in the augmented convolution or Turbo, or block decoding process.

The proposed methods also apply to the coding of a plurality of data messages. The data messages may include at least one data message associated with an active user, at least one data message associated with a pseudo active user and/or at least one of the data messages associated with an inactive user. (An active user is a user who is transmitting information using the communication system. A pseudo active user is a transmission initiated by the control system over the communication channel in order to mimic the presence of an active user. Data sent via a pseudo active user link carries no information and is not decoded by at the receiver of the communication system. An inactive user is an inactive link in the communication system where no data or information is transmitted or received.)

There may also be a permutation stage between each adjacent pair of coding stages if there are multiple coding stages. (A permutation stage comprises a reversible re-ordering of the connections between the outputs of one coding/decoding stage to the inputs of another coding/decoding stage.)

The majority logic coding blocks may be implemented as a look-up table. In this case, the improved coding is performed based on a look-up table.

The data messages may include data elements in ternary format, in polar, or in bi-polar binary formats. Moreover, each of the data messages may be derived from data received from an intermittent data source.

The proposed improvements apply to a spread-spectrum code division multiple access signal which includes coding of at least one data message stream based on Go-CDMA codes, scrambling the coded data message stream based on random codes, and transmitting the scrambled coded message stream over a communication channel. A plurality of data message streams may be coded, scrambled and transmitted together in this manner over a wireless medium. The method may be executed, for example, at a mobile communication unit or a base station. Moreover, the data message streams may be related, unrelated or a serial data stream. When the method is implemented at a base station, the data message streams may be associated with different mobile units, each of which may have associated with its multiple data streams. The method may include coding at least some of the data message streams based on non-Go-CDMA codes, scrambling the non-Go-CDMA coded data message streams based on random codes, and transmitting the scrambled non-Go-CDMA coded data message streams along with the Go-CDMA coded data message streams over a communication channel.

A method of decoding Go-CDMA signals may include receiving the scrambled coded message stream over a communication channel, unscrambling the coded data message stream and optimally decoding the data message stream based on the Go-CDMA codes. The coded data stream may include identification information that is perhaps determined from data in a pilot signal or any other communication protocol procedures. The method may include first receiving the scrambled coded message stream over a communication channel, unscrambling any non-Go-CDMA coded data message streams, separating these from the Go-CDMA coded data message streams based on the identification information. Next, separately decode both the non-Go-CDMA coded data message streams and the Go-CDMA coded data message streams.

### BRIEF DESCRIPTION OF THE FIGURES

The above described features and advantages of the present invention will be more fully appreciated with reference to the detailed description and appended figures, in which:

FIG. 1 depicts a communication channel with additive noise.

FIG. 2 depicts a multiple access, coding-decoding communication system according to an embodiment of the present invention.

FIG. 3A depicts functional block diagrams of a CDMA system, used in mobile communications, that includes coding and decoding blocks according to an embodiment of the present invention.

FIG. 3B depicts an illustrative view of a plurality of mobile units engaged in cellular communications over a noisy wireless channel with base sations.

FIG. 4A depicts a functional block diagram of a Go-CDMA system, used in mobile communications, that depicts the application of random scrambling codes to the coding and decoding scheme according to an embodiment of the present invention.

FIG. 4B depicts a functional block diagram of a Go-CDMA system, used in mobile communications, that depicts the application of random scrambling codes into the coding and decoding scheme which permits Go-CDMA coding and another coding scheme to be simultaneously implemented at the same base station or mobile unit. Alternatively, this can be implemented in a dual-mode mobile unit configuration at the mobile unit according to an embodiment of the present invention.

FIG. 5 depicts a general convolution coder having a coding rate of

$$\frac{m}{n}$$

and a constraint length of Mm.

FIG. 6 depicts a standard rate

$$\frac{1}{3}$$

convolution coder.

FIG. 7 depicts a basic block diagram of a Turbo coder.

FIG. 8 depicts an example of an eight states recursive systematic convolution coder.

FIG. 9 depicts the basic block diagram of a two-stage Turbo decoder.

FIG. 10 depicts the trellis representation of a finite state encoder.

FIG. 11 depicts a time invariant trellis diagram for a convolution code.

FIG. 12 depicts a time varying trellis diagram for a block code.

FIG. 13 depicts an optimum RAKE receiver architecture for receiving wide-band binary signals over a frequency selective channel.

FIG. 14 depicts a relation between the signal amplitude co-efficient ρ₁ and the total number of channels n.

FIG. 15 depicts in full lines a rate

$$\frac{1}{3}$$

convolution coder and in dotted line the effect of subsequent Go-CDMA coding and “soft” enhanced Go-CDMA decoding which converts this to an “equivalent” higher rate

$$\frac{1}{3 + 1}$$

convolution coding system.

FIG. 16A depicts a functional block diagram of an embodiment of Go-CDMA non-linear code division multiple access coding and decoding, together with convolution error-correction coding and decoding, and interleaving and de-interleaving within a transceiver of a communication system.

FIGS. 16B-16D depict variations to the implementation depicted in FIG. 16A.

FIG. 17 depicts an embodiment of an implementation of a two-stage Convolution/Go-CDMA coding and decoding channel spreading scheme.

FIG. 18 depicts in full lines a rate

$$\frac{2}{6}$$

convolution coder and in dotted lines the effect of subsequent Go-CDMA coding and “soft” enhanced Go-CDMA decoding, in a non-overlapped implementation, which converts this to an “equivalent,” higher, rate

$$\frac{2}{8}$$

convolution coding system.

FIG. 19 depicts in full lines a rate

$$\frac{2}{6}$$

convolution coder and in dotted lines the effect of subsequent Go-CDMA coding and “soft” enhanced Go-CDMA decoding, in an overlapped implementation, which converts this to an “equivalent” higher rate

$$\frac{2}{8}$$

convolution coding system.

FIG. 20 depicts a functional block diagram encompassing the channel error correction coding & decoding (330a & 330b), channel spreading & dispreading (210 & 220) and modulation forward & reverse mapping (211 & 221) of a communications system pertinent to the practical coding implementation of the present invention.

### DETAILED DESCRIPTIONS

I. Overview

Current technologies for multi-user communication systems include CDMA and time-division-multiple-access (TDMA). These technologies are widely used for single-cell, or multi-cell, mobile communication, with TDMA being the basis of the GSM mobile telephone system.

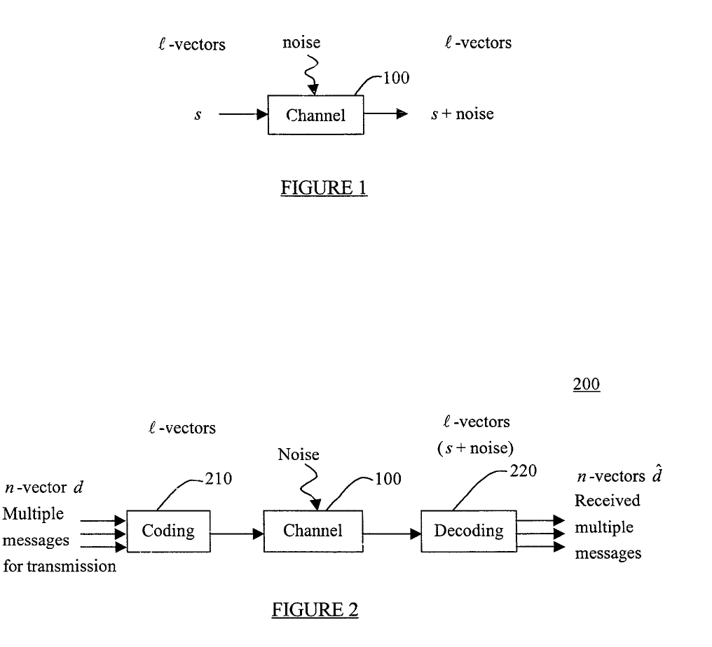

FIG. 1 illustrates an environment in which multi-user communication systems exist. Referring to FIG. 1, a communication channel 100 is depicted as having additive noise on it. The communication channel may be air, space, an electrical connection such as a wire, transmission line, or microwave element or an optical fiber, as examples. An incident signal s traversing the communications channel 100 is influenced by additive noise in the communication channel resulting in a signal (s+noise) at the far end of the transmission line.

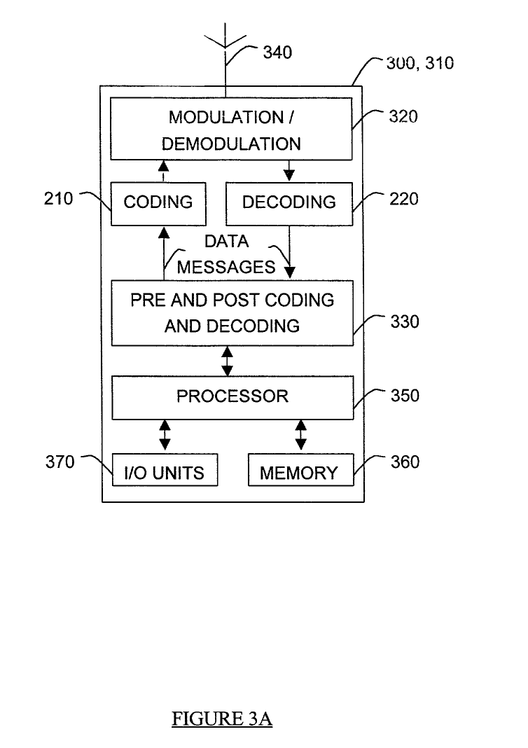

FIG. 2 depicts a schematic of a multiple-access, coding-decoding communication system 200. The system 200 includes multiple messages for transmission as inputs to a coding block 210. The coding block 210 codes the messages and transmits the coded messages as a composite signal over the noisy communications channel 100. The decoding block 220 receives the composite signal that includes noise and decodes the coded messages through a process that is in general the inverse of the coding process, at least in the case of zero channel noise, and approximates this otherwise.

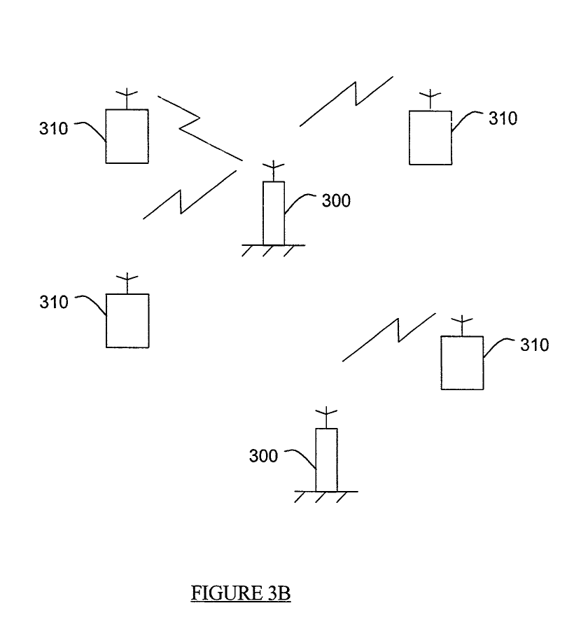

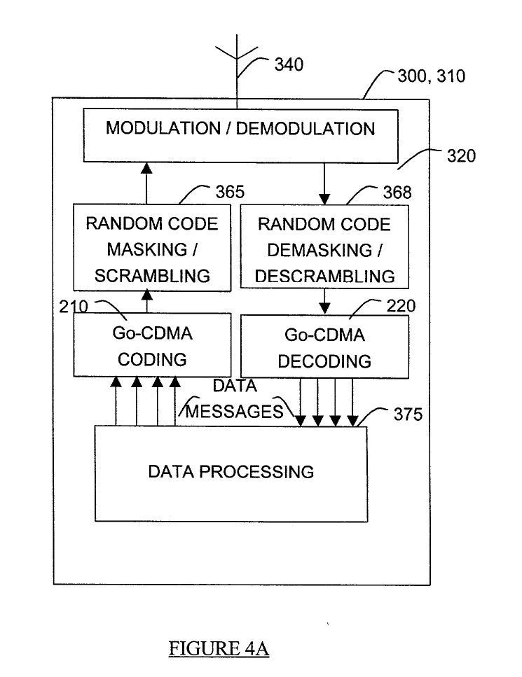

Both the coding block 210 and the decoding block 220 are depicted as single blocks. In the case of multiplexed optical fiber communications systems, for example, there may indeed be single coding and decoding blocks that interface with the optical fiber that is the communications channel 100. Alternatively, in mobile communications systems, for example, one or both of the coding block 210 and the decoding block 220 may be implemented as de-coupled coding or decoding blocks, one for each user, and each with a unique spatial position relative to each other. This situation is depicted in FIGS. 3A and 3B.

FIG. 3A, illustrates a communication system. The communication system may include, for example, a base station 300 or a mobile communication unit 310 such as is used in cellular communications. The system 300, 310 may include a modulation/demodulation unit 320 coupled to an antenna 340, coding and decoding units, 210 and 220, respectively, an optional pre- and post-coding and decoding unit 330, a processor 350, a memory 360 and I/O units 370.

The processor 350 may be a microprocessor, a micro-controller, a digital signal processor, an application specific integrated circuit, or any other device suitable for controlling the operation of the system 300, 310. The processor 350 controls the operation of the device 300 and 310 and may be coupled to each of the functional blocks within the device to control their operation. Alternatively, any or all of the functional blocks depicted, as within the device 300, 310 may be implemented on the processor. The processor may control the device 300, 310 by executing program instructions stored in the memory 360 causing the functional units to become operative, regardless of their physical embodiments.

The memory 360 stores data and may store program instructions for execution by the processor 350 or other elements within the devices 300, 310. The memory may include volatile memory, non-volatile memory or both. The memory may include, for example read-only memory (ROM) and read-only memory devices such as CD-ROM devices, hard and floppy disk drives, random access memory (RAM), databases and any other type of memory or memory device.

The I/O units 370 may include any type of input/output devices. These may include a display, a keyboard, a microphone, a speaker, a camera, a vibrating device, a modem for connecting to a network such as the PSTN, a local or wide area network or the interconnected network of servers, routers and bridges collectively known as the Internet.

During operation, the processor 350 may cause the device 300, 310 to open a communications channel via the antenna 340 with another communications device pursuant to the CDMA or TDMA protocol. In the case of wireless cellular telephony, the communications channel may be used to place a telephone call. The processor 350 also may receive signals from the I/O units 370 or the memory 360, such as voice or data signals, and may output data messages to the pre- and post-coding and decoding unit 330 based on the received data or voice signals. The data messages may in turn be sent through the coding unit 210 and the modulation/demodulation unit 320 and out from the antenna 340 pursuant to the appropriate communications protocol. Similarly in th% reverse direction, the processor may receive data messages via the antenna 340, the decoding unit 220 and, the pre- and post-decoding unit 330. The processor may then output a signal or other data, based on the received data messages, to one or more of the I/O units 370, or store the data in the memory 360. In this manner the device 300, 310 may perform communications functionality on behalf of a user of the device.

The pre- and post-coding and decoding block 330 is optional. Examples of its use would be to insert (or decipher in the case of decoding) error correcting codes into the data messages, to interleave or de-interleave data or to otherwise manipulate the data messages prior to coding or after decoding. In the case of inserting error correction codes, any error correction or error protection schemes may be used including cyclical redundancy check (CRC) schemes and forward error correction (FEC) schemes.

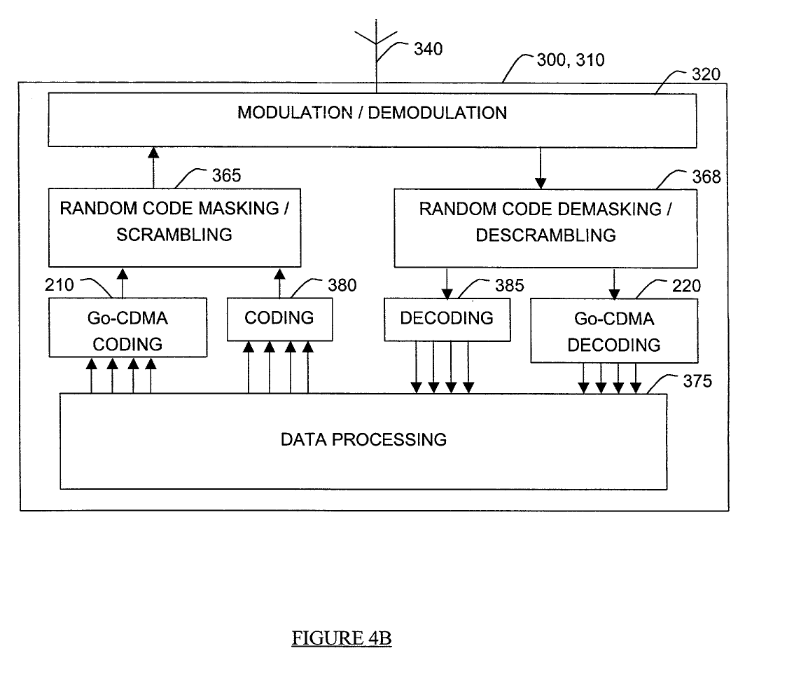

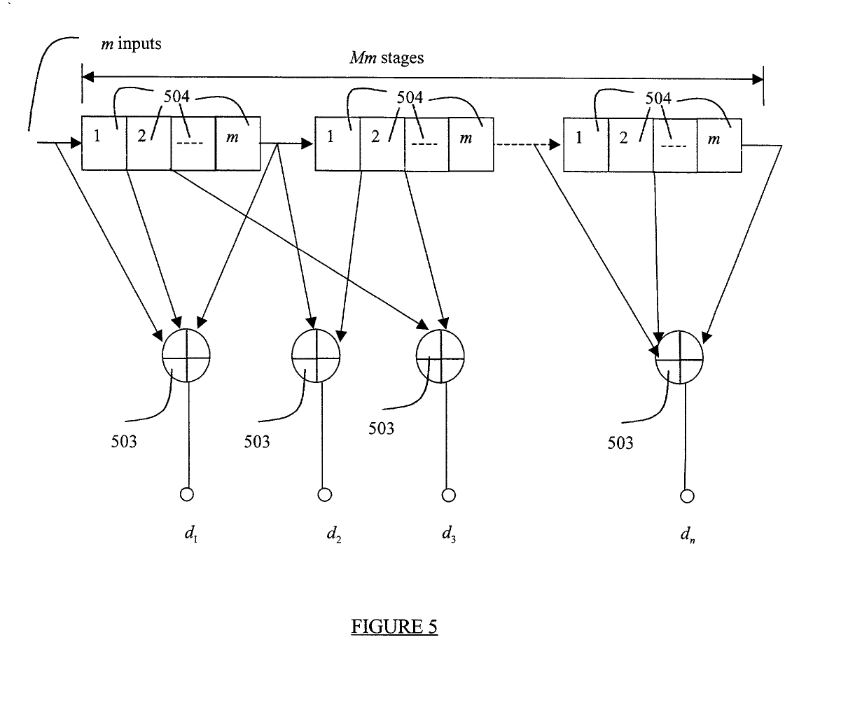

The coding and decoding blocks may be conventional CDMA or TDMA or Go-CDMA coding blocks as described in the co-pending U.S. patent application entitled “Method and Apparatus for Non-Linear Code-Division Multiple Access Technology” filed on Oct. 5, 2001 and hereby incorporated by reference herein. The coding and decoding blocks 210 and 220 may implement Go-CDMA coding and decoding schemes according embodiments of the present invention as well. Alternatively, both the Go-CDMA coding and CDMA coding may exist in mixed systems as shown in FIG. 4B.

The modulation/demodulation unit 320 may be implemented with any appropriate amplifier to create a modulated output signal s based on either the TDMA or CDMA scheme, including CDMA schemes with the Go-CDMA technology.

Consider a CDMA capable communications device 300, 310 which includes a processor or other device that executes program instructions to perform the coding and decoding functions of blocks 210 and 220. In this case, the memory 360 may be updated with data and programming instructions to configure the coding and decoding blocks 210 and 220 to implement the Go-CDMA coding and decoding scheme according to the present invention. The program instructions and data may be loaded into the memory 360 via one or more of the I/O units 370, or via data received from the antenna 340.

FIG. 3B depicts an illustrative view of a plurality of mobile units 310 engaged in cellular communications over a noisy wireless channel 100 with base stations 300. The mobile stations 310 and each of their respective coding units 210 may collectively be considered equivalent to the single coding unit 210 depicted in FIG. 2 for coding n data messages to transmit over a noisy channel 100. In this scenario, the base station unit and its decoding unit 220 may be considered equivalent to the single decoder 220 depicted in FIG. 2 for decoding n received data messages in a composite signal plus noise.

In the third generation standards for wide-band mobile communication, a CDMA approach has been chosen. A latent technology is Majority Logic Coding, which has not yet delivered significantly for any widely used communications system. This latent technology is the basis of the cross-referenced patent pending invention on Go-CDMA technology, and consequently of the present invention which is an enhanced Go-CDMA technology.

The Multinomial Structure of a Majority logic Coded Signal

Go-CDMA non-linear, code division multiple access technology makes use, in part, of either the sign or sgn majority logic functions, where:

$$\begin{matrix}sign ( x ) := \{ \begin{matrix}+ 1 & ; if x > 0 \\ 0 & ; if x = 0 \\ - 1 & ; if x < 0\end{matrix} ; and , \\ {sgn}_{+} ( x ) := \{ \begin{matrix}+ 1 & ; if x \geq 0 \\ - 1 & ; if x < 0\end{matrix} ; or , & \text{(1.1)} \\ {sgn}_{-} ( x ) := \{ \begin{matrix}+ 1 & ; if x > 0 \\ - 1 & ; if x \leq 0\end{matrix} . & \text{(1.2)}\end{matrix}$$

A majority logic coded signal such as a Go-CDMA coded signal s(τ)|τÅ[0,t] as a function of time τ, is defined as follows:

$$\begin{matrix}s ( τ ) = sign {\sum }_{i = 1}^{n} {d}_{i} {X}_{i} ( τ ) , or , & \text{(1.3)} \\ {s}_{\pm } ( τ ) = {sgn}_{\pm } {\sum }_{i = 1}^{n} {d}_{i} {X}_{i} ( τ ) , & \text{(1.4)}\end{matrix}$$

where i=1, . . . , n number of channels, dᵢ=±1 is the information bit of the i-th channel and Xᵢ(τ)|τ∈[0,t] is a bipolar code word of the i-th channel. The code words are piecewise constant during m equal time intervals in the time period [0,t]. For certain applications, it is desirable that the code words are orthonormal in that

$${\int }_{0}^{t} {X}_{j} ( τ ) {X}_{i} ( τ ) ⅆ τ = {δ}_{ij}$$

(τ)Xᵢ(τ)dτ=δᵢⱼ for i, j=1, . . . , n where δᵢⱼ=0 for i≠j, and δᵢⱼ=1 otherwise, but this is not always the case. In 1964, a following multinomial series structure for s(τ)|τ∈[0,t] was proposed as follows:

$$s ( τ ) = {ρ}_{0} + {ρ}_{1} {\sum }_{i = 1}^{n} {d}_{i} {X}_{i} ( τ ) + {ρ}_{2} {\sum }_{i = 1}^{n} {\sum }_{j = i + 1}^{n} {d}_{i} {d}_{j} {X}_{i} ( τ ) {X}_{j} ( τ ) + … \\ … + {ρ}_{n} {d}_{1} {d}_{2} … {d}_{n} {X}_{1} ( τ ) {X}_{2} ( τ ) … {X}_{n} ( τ ) , \qquad \text{(1.5)}$$

where formulas were provided to calculate only ρ₀, ρ₁, and ρₙ from n, as

$$\begin{matrix}{ρ}_{0} = 0 , \\ {ρ}_{1} = \{ \begin{matrix}{2}^{1 - n} ( \frac{\begin{matrix}n - 1 \\ n - 1\end{matrix}}{2} ) ; if n = odd , \\ {2}^{- n} ( \frac{\begin{matrix}n \\ n\end{matrix}}{2} ) ; if n = even ,\end{matrix} \\ {ρ}_{n} = \{ \begin{matrix}- {ρ}_{1} ; if n + 1 = a multiple of 4 , \\ {ρ}_{1} ; if n = 1 \neq a multiple of 4 ,\end{matrix} \\ \vert {ρ}_{1} \vert < {ρ}_{i} for i = 2 , 3 , … , n - 1\end{matrix} \qquad \text{(1.6)}$$

Here we observe that all possible selections give rise to only (n+1) linear equations in (n+1) unknowns ρ₀, ρ₁, . . . , ρₙ and can be solved for all ρᵢ for any integer n≧2. Likewise for the case s_{±}(τ), which is different from s(τ) when n is even, the same multinomial structure applies and unknowns ρ₀, ρ₁, . . . , ρₙ can be calculated. In fact, ρ₀=0 for the case s(τ), but ρ₀≠0 for s_{±}(τ) when n is even. When n is odd, s_{±}(τ)=s(τ) and for the unknowns ρ₀, ρ₁, ρ₂, . . . , ρₙ where ρ₀=ρ₂= . . . =ρₙ₋₁=0, thus, the ρᵢ coefficients for s_{±}(τ), where (n+1) is even, are given as ρ₁, ρ₁, ρ₃, ρ₃, . . . , ρₙ₋₂, ρₙ₋₂, ρₙ.

Again for certain applications, it is desirable that the functions Xᵢ(τ), Xᵢ(τ)Xⱼ(τ), . . . , X₁(τ)X₂(τ) . . . Xₙ(τ), be mutually orthogonal.

Optimum Maximum Likelihood Detection of Majority Logic Coded Signals

In the coding of data streams from n channels, since 2ⁿ different combinations of data are possible, 2ⁿ different signals s_{*}(τ)|τ∈[0,t] are also possible. Here the s_{*}(τ) denotes either s(τ) or s_{±}(τ). Thus an optimal detection of a majority logic, and in particular a Go-CDMA, coded n-bit signal data vector {d₁, d₂, . . . d₃} can be realized with a bank of 2ⁿ correlators, or matched filters, one for each of the 2ⁿ possible signals, to choose the one with the best match, according to standard least squares measures. The cost of this optimum detection algorithm is in the complexity of the detection structure that grows exponentially with the number of data channels n.

Conventional Sub-Optimal Detection of Majority Logic Coded Signals

A conventional majority logic decoding scheme estimates the information of dᵢ based on the following rule:

$${\hat{d}}_{i} = sign ( {z}_{i} ) ; {z}_{i} = {\int }_{0}^{t} {s}_{*} ( τ ) {X}_{i} ( τ ) ⅆ τ , for i = 1 , … , n . \qquad \text{(1.7)}$$

This detection algorithm may be employed to decode Go-CDMA non-linear code division multiple access technology. From (1.7) and (1.3) it can be observed that this detection algorithm, under the desired orthogonality, extracts the non-zero term in the multinomial structure of (1.5). This is effective because from (1.6) one can observe that the non-zero term in the multinomial structure of s(t) carries a significant portion of the information bit signal energy.

Refined Sub-Optimal Detection of Majority Logic Coded Signals

A practical refinement of the above sub-optimal detection for the case n odd has been to extract the last term in the multinomial structure of s(τ) in the decoding, as this term also carries a significant proportion of the information bit signal for dᵢ as follows:

(a) Evaluate the correlation zᵢ, for i=1, . . . , n+1, where

$$\begin{matrix}{z}_{i} = {\int }_{0}^{t} s ( τ ) {X}_{i} ( τ ) ⅆ τ , for i = 1 , … , n , \\ {z}_{n + 1} = {\int }_{0}^{t} s ( τ ) {X}_{1} ( τ ) {X}_{2} ( τ ) … {X}_{n} ( τ ) ⅆ τ .\end{matrix} \qquad \text{(1.8)}$$

(b) Estimate the information bit \hat{d}ᵢ, the following rule is observed:

\hat{d}ᵢ=sign(zᵢ) if |zᵢ|>|zₙ₊₁|, for i=1, . . . ,n (1.9)

otherwise,

$${\hat{d}}_{j} = \frac{sign ( {z}_{n + 1} ) sign ( {ρ}_{n} )}{{\hat{d}}_{1} , {\hat{d}}_{2} … {\hat{d}}_{j - 1} {\hat{d}}_{j + 1} … {\hat{d}}_{n}} , \qquad \text{(1.10)}$$

when |zᵢ|>|zⱼ| for i=1, . . . , j−1, j+1, . . . , n+1, and j=1, . . . , n.

This refinement may yield a better estimate of the n information bits by replacing the weakest information bit estimate \hat{d}ⱼ with an estimate based on the correlation values from the last term of (1.5). This is the case in low noise when:

(a) Error occurs at the point of the smallest correlation coefficient value, |zⱼ|;

(b) All other information bits \hat{d}ᵢ are error free, where i=1 . . . n and i≠j.

Here we observe that the same approach can be applied for the case when n is even as well as when n is odd simply with working with s_{±}(τ) instead of s(τ).

Go-CDMA Codes

These are described in co-pending U.S. patent application entitled “Method and Apparatus for Non-Linear Code-Division Multiple Access Technology” filed on Oct. 5, 2001 and hereby incorporated by reference herein. In summary, these are codes of the form of a generator matrix G with elements in the set {−1, +1} such that for bipolar vectors d with elements in the set {−1, +1}, then \hat{d}:=sgn_{±}[G^{T} sgn_{±}(Gd)]=d, and if d is ternary, or in a specified subclass of ternary data, then d^{T}|\hat{d}−d|=0, where |x| is the magnitude of x. This means that in a building block for a multi-access communication system, active user bipolar data, and possibly pseudo-active user data, and zero inactive user “data” forming a vector of data d can be coded as s=sgn_{±}(Gd). This is in turn transmitted and decoded as

\hat{d}:=sgn_{±}[G^{T}sgn_{±}(s+channel noise)] (1.11)

for error-free communication in the event of zero channel noise, and as it happens a robust estimation otherwise.

Multi-Stage Go-CDMA Coding

Parallel coding or decoding blocks constitute a coding or decoding stage, and concatenating these stages forms a multistage coding and decoding system. Intermediate stages can involve various permutation operations.

Convolution Coding

Convolution coding and decoding techniques may be used to code signals for transmission according to an embodiment of the present invention. An example convolution decoding technique is maximum likelihood decoding known as the Viterbi Algorithm.

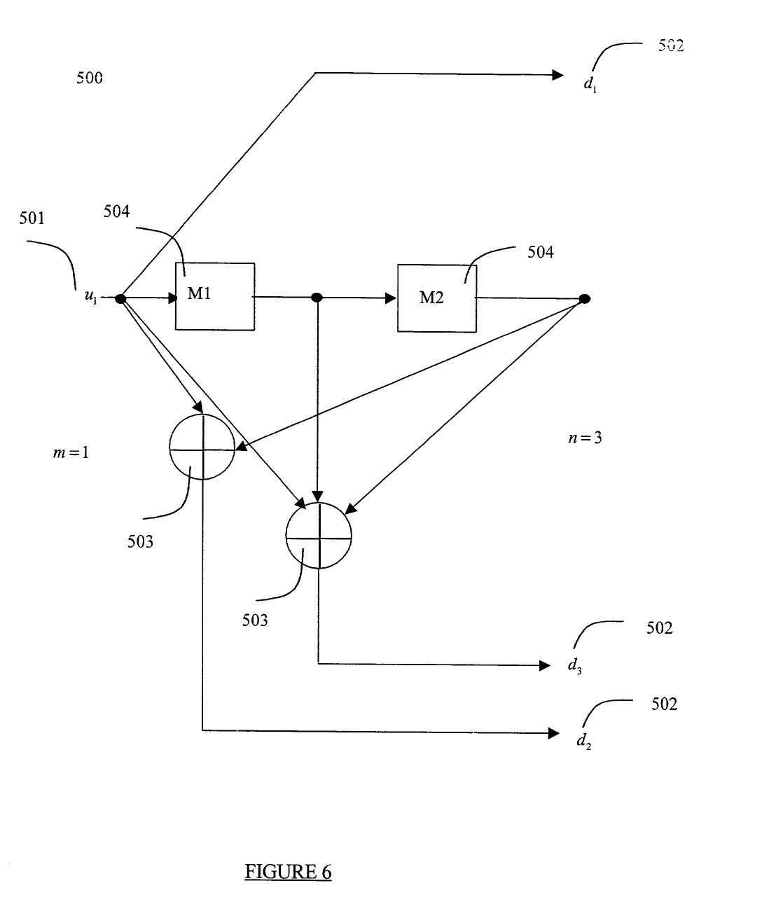

A convolution coding is achieved by passing the information sequence to be transmitted through a linear finite state register. In general, with reference to FIG. 5, a shift register 504 consists of M (m-bit) stages and n linear algebraic function generators 503. The input data 501 to the coder 500, which is assumed to be binary, is shifted into and along the shift register 504, m bits at a time. The number of output bits for each m-bit input sequence is n bits. Consequently, the code rate is defined as

$$\frac{m}{n} .$$

The parameter M is called the constraint length of the convolution code.

One method for describing a convolution code is by its generator matrix. In general, the generator matrix for a convolution code is semi-infinite since the input sequence is semi-infinite in length. As an alternative to specifying the generator matrix, we specify the finite-dimensional generating system. We specify a set of n vectors, one vector for each of the n modulo-2 adders 503. Each vector has dimension Mm and contains the connections of the coder 500 to modulo-2 adder 503.

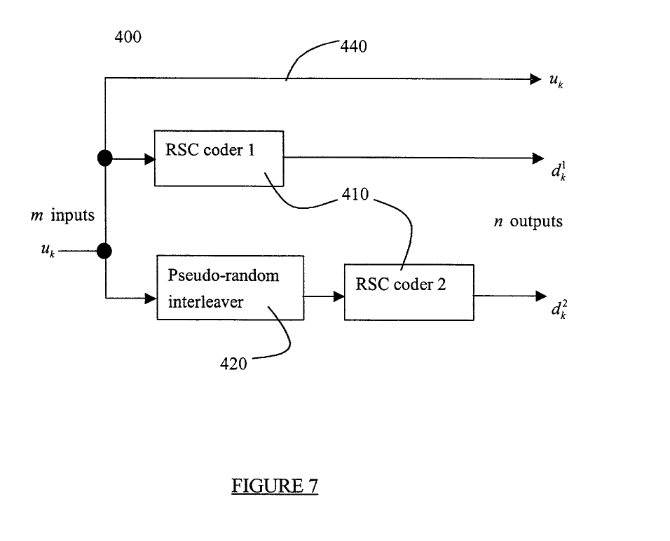

To be specific, let us consider the binary convolution coder 500 with constraint length M=3, m=1, and n=3, which is shown in FIG. 6. Initially, the shift register 504 is assumed to be in the all-zero state. Suppose the first input bit is a ‘1’. Then the output sequence of 3 bits is ‘1 1 1’. Suppose the second bit is a ‘0’. The output sequence will then be ‘0 0 1’. If the third bit is a ‘1’, the output will be ‘1 0 0’, and so on. Now, suppose we number the outputs of the function generators that generate each three-bit output sequence as 1, 2, and 3, from top to bottom, and similarly number each corresponding function generator. Then, since only the first stage is connected to the first function generator (no modulo-2 adder is needed), the generator is

g₁=[1 0 0]. (1.12)

The second function generator is connected to stages 1 and 3. Hence,

g₂=[1 0 1]. (1.13)

Finally,

g₃=[1 1 1]. (1.14)

The generators for this code are sometimes more conveniently given in octal form as (4,5,7).

Unlike a block code, which has a fixed length n, a convolution coder is basically a finite-state machine. Therefore, optimum decoding of a convolution coded sequence involves a dynamic-programming search through the trellis for the most probable sequence. Depending on whether the detector following the demodulator performs hard or soft decisions, the corresponding metric in the trellis search may be either a Hamming metric or Euclidean metric, respectively. An optimum decoder for convolution coding is termed the Viterbi Algorithm, which is a maximum-likelihood sequence estimator.

Sufficient details on the use of convolution coding in this invention are provided in the body of the text, but more material on standard convolution coding and decoding, definitions on different code metrics and an optimum Viterbi Algorithm can be found in standard textbooks. Any convolutional coding and decoding scheme may be used according to the present invention.

Turbo Coding

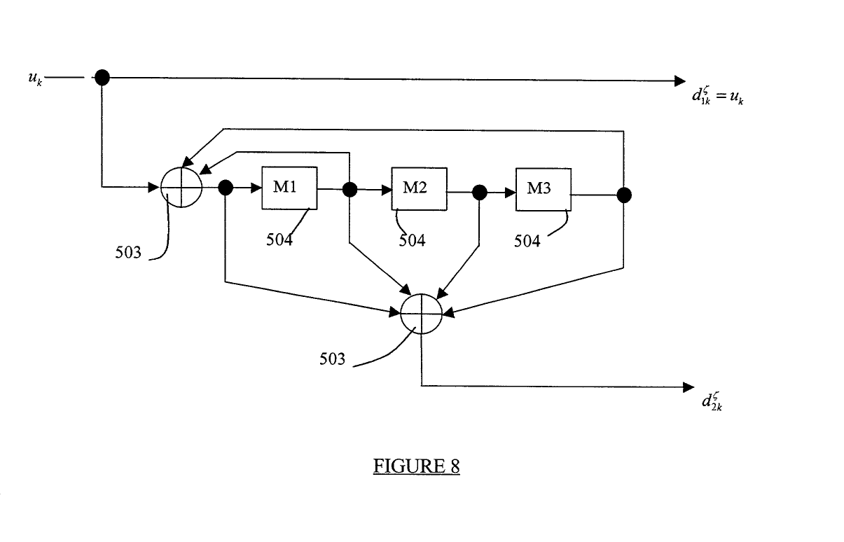

In its most basic form, the coder of a Turbo coder 400 consists of two constituent systematic coders 410 joined together by means of an interleaver 420, as illustrated in FIG. 7. Turbo codes use a pseudo-random interleaver 420, which operates only on the systematic bits. There are two reasons for the use of an interleaver in a Turbo code, namely:

To tie together errors that are easily made in one half of the Turbo code to errors that are exceptionally unlikely to occur in the other half. This is indeed the main reason why Turbo coding performs better than traditional codes.

To provide robust performance with respect to mismatch decoding, which is a problem that arises when the channel statistics are not known or have been incorrectly specified.

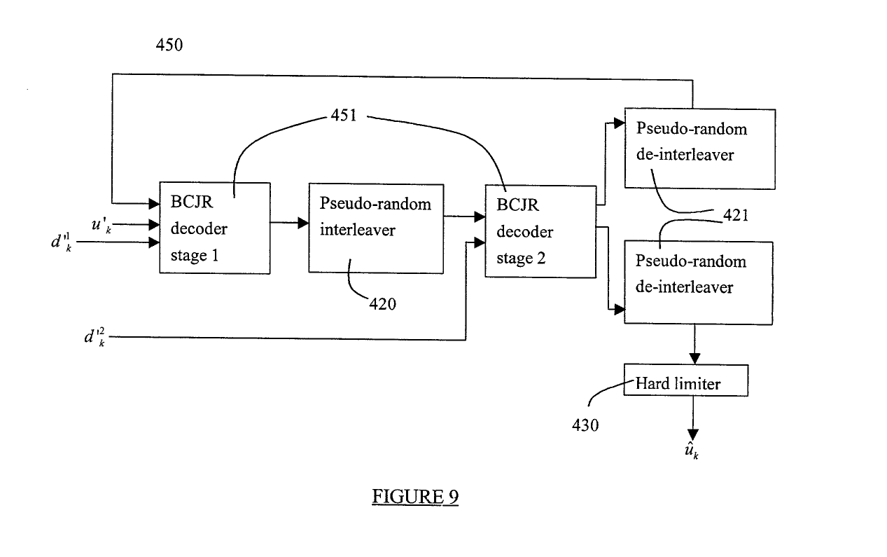

Typically, but not necessarily, the same code is used for both constituent coders 410 in FIG. 7. The constituent codes recommended for Turbo codes are short constraint-length recursive systematic convolution (RSC) codes. An example of an eight-state RSC coder 410 is given in FIG. 8. The reason for making convolution code recursive (i.e., feeding one or more tap outputs in the shift register back to the input) is to make the internal state of the shift register depend on past outputs. This affects the behavior of the error patterns (a single error in the systematic bits produces an infinite number of parity errors), with the result that a better performance of the overall coding strategy is attained. It is also known that every RSC coder 410 has an equivalent standard convolution coder by the way of conversion using specific transformation algorithms.

In FIG. 7 the input is applied directly to Coder 1, and the pseudo-randomly reordered version of the same data stream is applied to Coder 2. The systematic bits (i.e., original message bits) and the two sets of coded bits are generated by the two coders 410 constitute the output of the Turbo coder 400. Although the constituent codes are convolution codes, in reality Turbo codes are block codes with the block size being determined by the size of the interleaver 420. Moreover, since both RSC coders 410 in FIG. 7 are linear, we may describe Turbo codes as linear block codes.

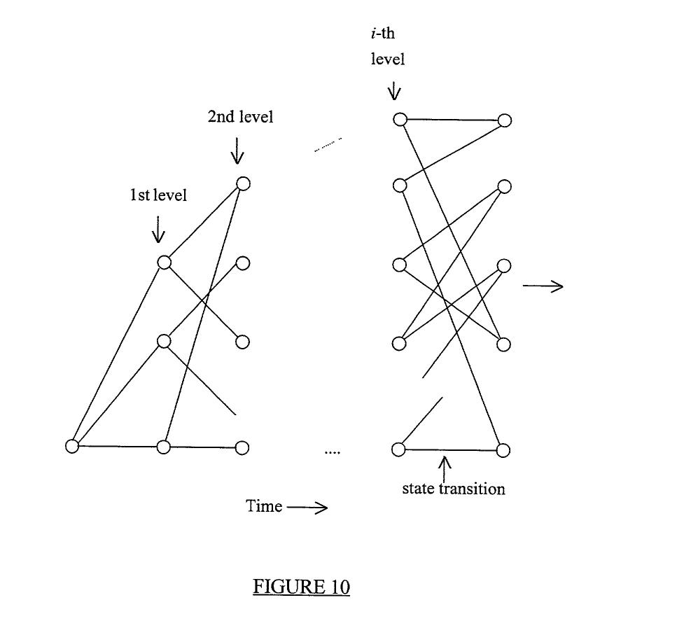

At the receiver, a two-stage Turbo decoder 450, as depicted in FIG. 9, may be used to decode the received signal. In the example depicted, each of the two decoding stages 451 uses a Bahl, Cocke, Jelinek and Raviv (BCJR) algorithm to solve a maximum “a posteriori probability” (MAP) detection problem. The BCJR algorithm differs from the Viterbi algorithm in two fundamental respects:

1. The BCJR algorithm is a “soft-input, soft-output” decoding algorithm with two recursions, one forward and the other backward, both of which involve soft decisions. In contrast, the Viterbi algorithm is a “soft-input, hard-output” decoding algorithm, with a single forward recursion involving soft decisions; the recursion ends with a hard decision, whereby a particular survivor path among several others is retained. In computational terms, the BCJR algorithm is therefore more complex than the Viterbi algorithm because of the backward recursion.

2. The BCJR algorithm is a MAP decoder in that it minimizes the bits error by estimating “a posteriori probabilities” of the individual bits in a code word; to reconstruct the original data sequence, the soft outputs of the BCJR algorithm are hard-limited. On the other hand, the Viterbi algorithm is maximum likelihood sequence estimator in that it maximizes the likelihood function for the whole sequence, not each bit. As such, the BCJR algorithm can be slightly better than the Viterbi algorithm; it is never worse.

At the Turbo decoder, as depicted in FIG. 9, the received systematic bit u′ₖ and coded bit d′ₖ¹, together with the feedback data from the prior decoding process, are processed by a stage one BCJR decoder 451. The result of this process is then interleaved by a pseudo-random interleaver 420. The output of the interleaver is further processed by the stage two BCJR decoder 451, together with the received coded bit d′ₖ². The outcome of this stage two BCJR decoder 451 is then de-interleaved by two separate pseudo-random de-interleavers 421. The output of one of the de-interleavers is fed back into the stage one BCJR decoder for the decoding process following received bits. Output from the other pseudo-random de-interleaver is passed through a hard limiter threshold device 430 to attain an estimate of the transmitted information bit.

Sufficient details on the use of Turbo coding in this invention are provided in the body of the text, but more material on standard Turbo coding and decoding, and the optimum BCJR Algorithm can be found in standard textbooks. It will be understood that any Turbo coding and decoding scheme may be used in accordance with the present invention.

Linear Block Coding

Standard linear coding techniques, such as code generating matrices, parity check matrices and syndrome tables may be used as part of the coding process according to embodiments of the present invention.

A block code comprises a set of fixed-length vectors called code words. The length of a code word is the number of elements in the vector and is denoted by n. The elements of a code word are selected from an alphabet of q elements. When the alphabet consists of two elements, 0 and 1, the code is a binary code. When the elements of a code word are selected from an alphabet having q elements (q>2), the code is non-binary. There are 2ⁿ possible code words in a binary block code of length n. From these 2ⁿ code words, we may select V=2^{m} code words (m<n) to form a code. Thus, a block of m information bits is mapped into a code word of length n selected from the set of V=2^{m} code words. The resulting block code would have a rate of

$$\frac{m}{n} .$$

Let u_{V1},u_{V2}, . . . ,u_{Vm} denote the m information bits coded into the row vector code word N_{V}. Thus, the vector of m information bits into the linear block code coder is denoted by

U_{V}=[u_{V1}u_{V2} . . . u_{Vm}] (1.15)

and the output of the coder is the vector

N_{V}=[n_{V1}, n_{V2} . . . n_{Vn}] (1.16)

The encoding operation performed in a linear binary block coder can be represented by a set of n equations of the form

n_{Vj}=u_{V1}g₁ⱼ+u_{V2}g₂ⱼ+ . . . +u_{Vm}gₘⱼ, j=1,2, . . . , n (1.17)

where gᵢⱼ∈{0,1} and uₓᵢgᵢⱼ represents the product of uₓᵢ and gᵢⱼ. These equations can also be represented in matrix form as

N_{V}=U_{V}G (1.18)

where G, called the generating matrix of the code, is

$$G = [ \begin{matrix}{g}_{11} & {g}_{12} & ⋯ & {g}_{1 n} \\ {g}_{21} & {g}_{22} & ⋯ & {g}_{2 n} \\ ⋮ & ⋮ & . & ⋮ \\ {g}_{m1} & {g}_{m2} & ⋯ & {g}_{mn}\end{matrix} ] . \qquad \text{(1.19)}$$

Any generating matrix of a linear block code of rate

$$\frac{m}{n}$$

can be reduced by row operations (and column permutations) to the “systematic form,”

$$G = [ {I}_{m} \vert P ] = [ \begin{matrix}1 & 0 & 0 & ⋯ & 0 & {p}_{11} & {p}_{12} & ⋯ & {p}_{n - m} \\ 0 & 1 & 0 & ⋯ & 0 & {p}_{21} & {p}_{22} & ⋯ & {p}_{2 n - m} \\ ⋮ & ⋮ & ⋮ & . & ⋮ & ⋮ & ⋮ & . & ⋮ \\ 0 & 0 & 0 & ⋯ & 1 & {p}_{m1} & {p}_{m2} & ⋯ & {p}_{mn - m}\end{matrix} ] \qquad \text{(1.20)}$$

where iₘ is the m×m identity matrix and P is a m×(n−m) matrix that determines the n−m redundant bits or parity check bits. For a systematic linear block code and its generator matrix G is given in its “systematic form”, then the parity check matrix H is

H=[−P′|I_{n-m]} (1.21)

where P′ is the transpose of the P matrix. The negative sign in −P′ may be dropped when dealing with binary codes, since modulo-2 subtraction is identical to modulo-2 addition.

The generator matrix G is used in the encoding operation at the transmitter. On the other hand, the parity check matrix H is used in the decoding operation at the receiver. In the context of the latter operation, let r denote the 1×n received vector that results from sending the code vector c over a noisy channel. Thus, r can be expressed in the form

r=c+e (1.22)

where e is called the error vector or error pattern. The i-th element of e equals ‘0’ if the corresponding element of r is the same as that of c. On the other hand, the i-th element of e equals ‘1’ if the corresponding element of r is different from that of c, in which case an error is said to have occurred in the i-th location. The receiver has the task of decoding the code vector c from the received vector r. The algorithm commonly used to perform this decoding operation first computes a 1×(n−m) vector called the syndrome. Given a 1×n received vector r, the corresponding syndrome is defined as

syndrome=rH′ (1.23)

where H′ is the matrix transpose of the parity check matrix H. A complete table of syndromes is usually known as a syndrome table.

Sufficient details on the use of linear block coding in this invention are provided in the body of the text, but more material on standard block coding and decoding can be found in standard textbooks. It will be understood that any linear block coding scheme may be used according to embodiments of the present invention.

Trellis Coding

A code trellis is a graphical representation of a code, convolution or block, in which every path represents a codeword (or code sequence). This representation makes it possible to implement maximum likelihood decoding (MLD) of a code with significant reduction in decoding complexity. The most well known trellis-based MLD algorithm is the Viterbi algorithm. The convolution code trellis representation, together with the Viterbi decoding algorithm, has resulted in a wide range of applications of convolution codes for error control in digital communications over the last two decades. Trellis representation of linear block codes has also resulted in efficient MLD schemes for linear block codes.

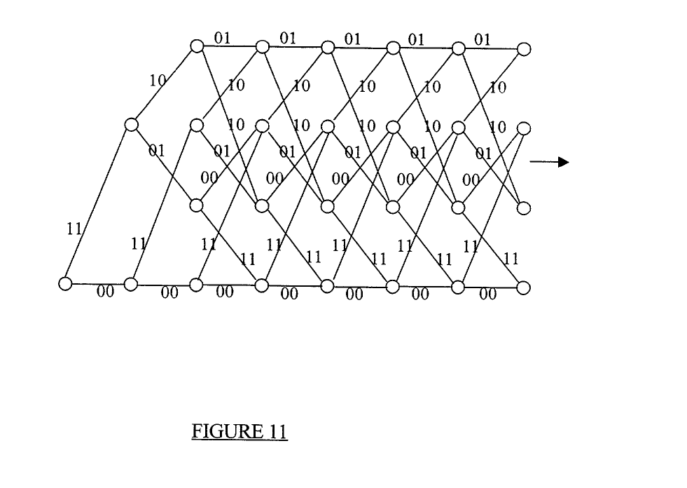

An encoder for a linear code, which encompasses both convolution and block codes, with a finite memory, for which the output code bits at any time instant during an encoding interval Γ={0,1,2, . . . } are uniquely determined by the current input information bits and the state of the encoder at the time can be modeled as a finite state machine. With this model, a representation of the dynamic behavior of the encoder is realized in the form of a trellis diagram, as shown in FIG. 10. The trellis encoder for the convolution coding process has a trellis mapping that begins from the zero state and progresses to the next state depending on the next input of the system. Usually, for a given system constraint length, after the first few levels, the trellis mapping will reach a transient state which is a repetition of the previous state. Typically a trellis encoder consists of a finite state coder followed by a mapping block that maps the outputs of the coder to signals in a given signal constellation.

A trellis decoder, in general, consists of a bank of filters and a MLD decoder (such as the Viterbi decoder). Each filter matches to a signal in the given constellation. The outputs of the filters are used to compute the branch metrics measured by the Euclidean distance. The metrics are used in the MLD decoder to determine the maximum likelihood input sequence.

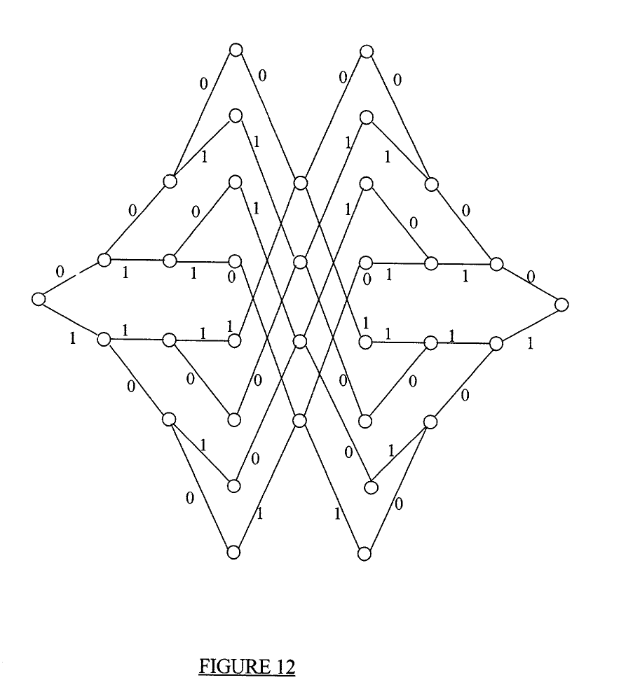

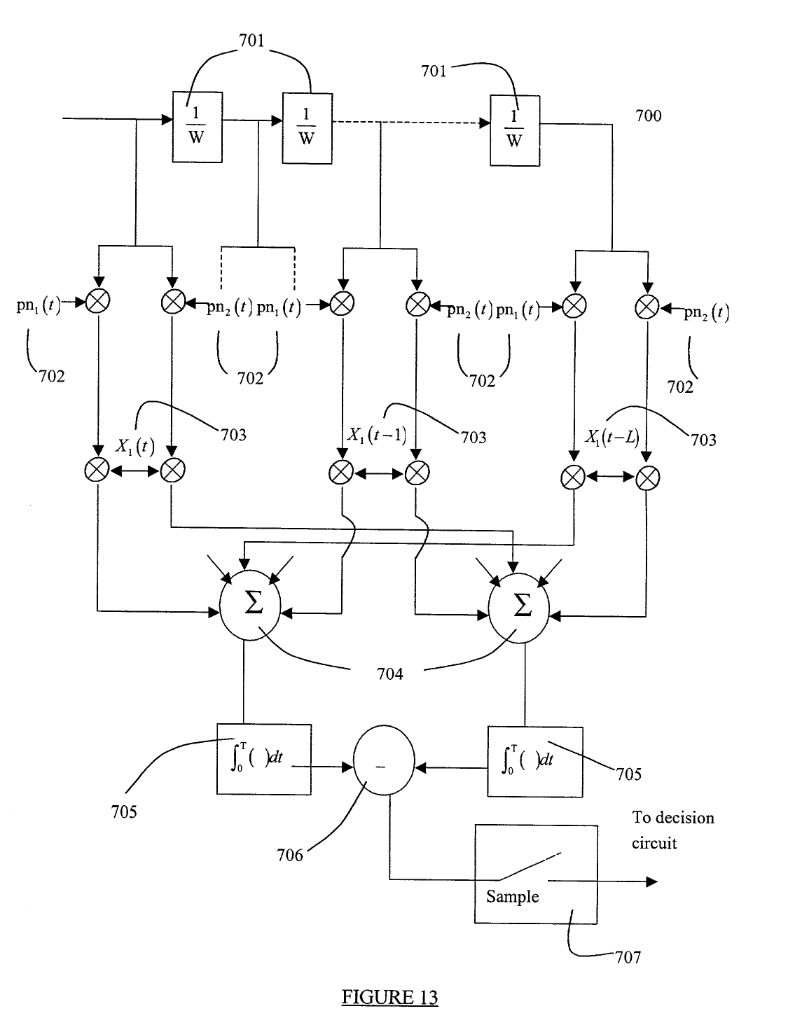

A trellis diagram for a convolution code is, in general, time invariant. However, a trellis diagram for a linear block code is usually time varying. FIGS. 11 and 12 depict a time invariant trellis diagram for a convolution code and a time varying trellis diagram for a linear block code, respectively.

Sufficient details on the trellis representation of the linear coding, both convolution coding and linear block coding, in this invention are provided in the body of the text, but more material on standard trellis coding and decoding, definitions on different trellis code metrics and the optimum mapping of code trellis on to modulation signal constellation can be found in standard textbooks. Any trellis coding and decoding scheme may be used according to embodiments of the present invention.

Convolution or Turbo or Block Coding with Trellis Coded Modulation

The output from either a convolution or Turbo or block error correction coding process may be mapped to a set of trellis code words with either maximum Euclidean or maximum Hamming distance. Such mappings may be done based on the Trellis Coded Modulation (TCM) technique proposed by Ungerboeck in 1982, or a derivation of the technique.

The optimum detector for such TCM based systems is the Maximum Likelihood Detector (MLD). MLD based detectors usually have hardware complexities that increase exponentially with the total numbers of possible signals to be detected.

Any trellis coded modulation and demodulation scheme may be used according to embodiments of the present invention. One of such TCM based scheme is to map the outputs from the embodiments of the present invention to non-linear block code matrices.

Non-Linear Code Matrices

The non-linear code matrices are rectangular non-linear code matrices, constructed from smaller non-linear and linear code matrices satisfying the Plotkin bound, wherever possible. For such non-linear code word matrices, they are constructed using the Levenshtein's construction. When a non-linear code word matrix is found to be not within the Plotkin bound, then other construction methods, such as the |u|u⊕v| construction methodology is used. Since the latter non-linear code word matrices are not within the Plotkin's bound, they do not have the optimum minimum code distances for their particular size. Nonetheless, the minimum distances for these non-linear code word matrices may have the largest possible values.

The Plotkin bound is an upper bound that dictates the maximum size possible for a non-linear code word matrix for a given minimum code distance cₘᵢₙ_{_{—}}_{dist}.

The Plotkin Bound

If cₘᵢₙ_{_{—}}_{dist} is even and 2cₘᵢₙ_{_{—}}_{dist}>l, then

$$m \leq 2 [ \frac{{c}_{min\_dist}}{2 {c}_{min\_dist} - l} ] ,$$

where, l is the length of the non-linear code word and 2^{m} is the number of possible non-linear code words. If cₘᵢₙ_{_{—}}_{dist} is odd and 2cₘᵢₙ_{_{—}}_{dist}+1>l, then

$$m \leq 2 [ \frac{{c}_{min\_dist} + 1}{2 {c}_{min\_dist} + 1 - l} ] .$$

The Plotkin bound is a good measure of the optimum minimum code distance for a given size of non-linear block codes.

The Levenshtein's Construction

This construction methodology makes use of the existence of Hadamard matrices with smaller sizes. To construct the non-linear code ε, the following definition is required:

1. If 2cₘᵢₙ_{_{—}}_{dist}>l≧cₘᵢₙ_{_{—}}_{dist}, define

$$κ = \frac{{c}_{min\_dist}}{2 {c}_{min\_dist} - l} , and$$

and

α=cₘᵢₙ_{_{—}}_{dist}(2κ+1)−l(κ+1), β=κl−cₘᵢₙ_{_{—}}_{dist}(2κ−1).

2. Both α and β are non-negative integers and

l=(2κ−1)α+(2κ+1)β, cₘᵢₙ_{_{—}}_{dist}=κα+(κ+1)β.

Thus, when l is even, so are α and β. When l is odd and κ is even, then β is even, otherwise, when both l and κ are odd, then α is even.

With the Levenshtein construction, the non-linear code ε is:

$$ξ = \{ \begin{matrix}\frac{α}{2} {A}_{4 κ}^{′} ⊕ \frac{β}{2} {A}_{4 κ + 4}^{′} , & if n even ; \\ α {A}_{2 κ} ⊕ \frac{β}{2} {A}_{4 κ + 4}^{′} , & if n odd , κ even ; \\ \frac{α}{2} {A}_{4 κ}^{′} ⊕ β {A}_{2 κ + 2} , & if n and κ odd .\end{matrix}$$

where ⊕ is modulo 2 addition, Aₙ is the binary Hadamard (all elements of the set {0,1}) of size n with the first column deleted, and A′ₙ is the matrix set derived from code words beginning with 0 in Aₙ matrix, and with the initial zero deleted.

The |u|u⊕v| Construction

This construction methodology builds non-linear code word matrices from smaller ones in the following manner:

1. Given a (l,2^{m}^{₁}, cₘᵢₙ_{_{—}}_{dist}_{₁}) code ε₁ and a (l,2^{m}_{₂}, cₘᵢₙ_{_{—}}_{dist}_{₂}) code ε₂, with the same length, a new non-linear code ε₃ can be formed consisting all vectors

ε₃=|u|u⊕v|, u∈ε₁, v∈ε₂,

where all the non-linear code words are in binary {0,1}.

2. The resultant code ε₃ is a (2l,2^{m}_{₁}^{m}_{₂}, cₘᵢₙ_{_{—}}_{dist}_{₃}=min{2cₘᵢₙ_{_{—}}_{dist}_{₂},cₘᵢₙ_{_{—}}_{dist}_{₂}}) code.

Together with the above construction methodologies, the non-linear code matrices mapping for the output of the present invention may be extracted from the rows and columns of orthogonal Hadamard matrices or constructed from smaller non-linear code word matrices or derived from the output signals themselves.

RAKE Receiver Architectures

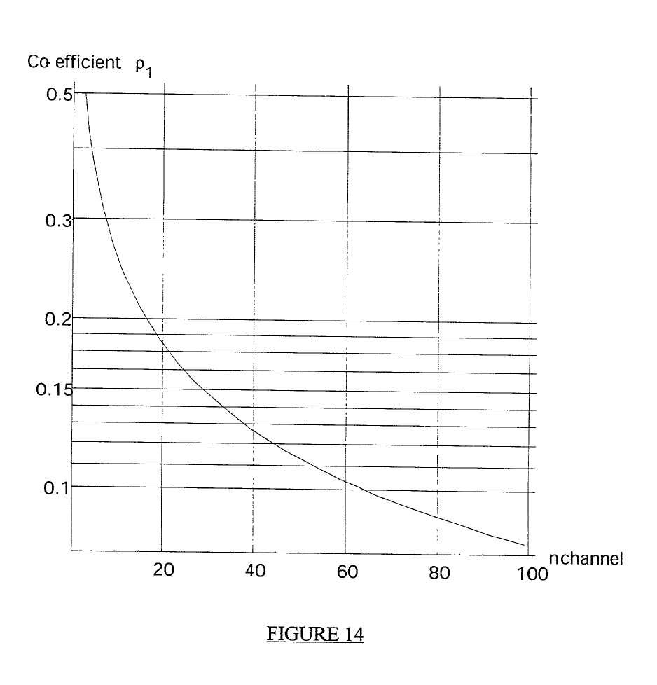

When dealing with signals propagating over a frequency-selective wide-band channel, there is usually the problem of multi-path fading. If the L different multi-paths are statistically independent then at the receiver we can obtain L replicas of the same transmitted signal. Thus, a receiver that processes the received signal in an optimum manner will achieve the performance of an equivalent L-th order diversity communications system. A RAKE receiver is a diversity-optimized receiver. FIG. 13 depicts an ideal realization of a RAKE receiver employing a single delay line, through which is passed the received signal r(t). The signal at each tap is correlated with Xₙⱼ(t)pn_{ch}(t), where j=1,2, . . . , L and ch=1,2. This receiver structure 700 is shown in FIG. 13. In effect, the tapped delay receiver 700 attempts to collect the signal energy from all the signal paths that fall within the span of the delay line and carry the same information. In FIG. 13, each detection path is separated by a delay 701 of

$$\frac{1}{W}$$

at each tap. The received wide-band signal is first unscrambled by the pseudo random sequence pnᵢ 702 for both the in-phase channel (i=1), also known as real channel, and orthogonal phase (i=2) channel, also known as the imaginary phase channel. This is followed by de-correlating the received signal at each path against the signaling interval Xₙ(t) for different chip offsets. In FIG. 13, this is done in steps 703, 704 and 705. Moreover at step 704, signals from all received paths are summed together to maximize the received signal strength. Finally, step 706 removes the phase difference between the real and imaginary phase channels and the detected information is fed into a sample and hold device 707, ready for further decoding.

It is important to note here that should the received signal have a known signature or symbol, then “RAKE symbol-detection” can be done using the matched filter approach of FIG. 13, otherwise only a “RAKE chip-detection” approach can be attempted. The former approach is easier to implement and can be made quite efficient, but the latter approach requires a very complex chip signal tracking mechanism and is prone to inter-symbol interference.

Sufficient details on the use of RAKE receiver architecture in this invention are provided in the body of the text, but more material on different RAKE receiver architectures can be found in standard textbooks. It will be understood that any RAKE receiver scheme may be implemented according to embodiments of the present invention.

Interleaving

An interleaver is an input-output mapping device that permutes the ordering of a sequence of symbols from a fixed alphabet in a completely deterministic manner; that is, it takes the symbols at the input and produces identical symbols at the output but in a different temporal order. Thus, the interleaver is an effective method for dealing with bursty error channels, as it interleaves the coded data in such a way that the bursty channel is transformed into a channel having independent errors.

The interleaver can be of many types, of which the periodic and pseudo-random are two. The interleaver also can take one of two forms: a block structure or a convolution structure. The latter is matched for use with convolution coding schemes.

Sufficient details on the use of interleaving in this invention are provided in the body of the text, but more material on standard interleaving and de-interleaving can be found in standard textbooks. Any interleaving and de-interleaving scheme may be implemented according to embodiments of the present invention.

II. Go-CDMA Detection Schemes.

Enhanced Go-CDMA Decoding.

The refined sub-optimal detection algorithm (1.8)-(1.10) for majority logic encoding may be advantageously applied to Go-CDMA decoding blocks. The application may be particularly useful under the following conditions: there is a low noise environment, and the Go-CDMA decoding block is either in the last stage of decoding, or is followed by a convolution, Turbo or block decoding.

Enhanced Information Flow to the Next Stage Decoding.

According to an embodiment of the present invention, the Go-CDMA decoding blocks have outputs zᵢ, for i=1, . . . , n, by zᵢ, for i=1, . . . , n+1, given in (1.9), and passes the additional bit zₙ₊₁ to the next stage of decoding. The following cases for n=3, n=5 have special properties:

Case of n=3. When the number of channels n is equal to 3, then the Go-CDMA coded signal is:

$$s ( t ) = \frac{1}{2} {\sum }_{i = 1}^{3} {d}_{i} {X}_{i} ( t ) - \frac{1}{2} ( {d}_{1} {d}_{2} {d}_{3} {X}_{1} ( t ) {X}_{2} ( t ) {X}_{3} ( t ) ) . \qquad \text{(1.24)}$$

It turns out that in the noise free case, the information bits satisfy dᵢ=zᵢ, for i=1,2,3, and d₁d₂d₃=−z₄. Indeed, for 3×l Go-CDMA codes the Xᵢ(.) are orthonormal and orthogonal to the product X₁(.)X₂(.)X₃(.), so extraction of dᵢ=zᵢ, for i=1,2,3, and d₁d₂d₃=−z₄ can be achieved by de-correlation.

Case of n=5. When the number of channels n is equal to 5, then the Go-CDMA coded signal is:

$$\begin{matrix}s ( t ) = \frac{3}{8} {\sum }_{i = 1}^{5} {d}_{i} {X}_{i} ( t ) + \frac{1}{8} {\sum }_{i = 1}^{5} {\sum }_{j = i + 1}^{5} {\sum }_{k = j + 1}^{5} {d}_{i} {d}_{j} {d}_{k} {X}_{i} ( t ) {X}_{j} ( t ) {X}_{k} ( t ) + \\ \frac{3}{8} ( {d}_{1} {d}_{2} {d}_{3} {d}_{4} {d}_{5} {X}_{1} ( t ) {X}_{2} ( t ) {X}_{3} ( t ) {X}_{4} ( t ) {X}_{5} ( t ) )\end{matrix} \qquad \text{(1.25)}$$

For 5×l Go-CDMA codes, the Xᵢ(.) are orthonormal and orthogonality also holds among Xᵢ(.), Xᵢ(.)Xⱼ(.)Xₖ(.) and X₁(.)X₂(.)X₃(.)X₄(.)X₅(.). From (1.25) it can be seen then that the information bits dᵢ and products dᵢdⱼdₖ, and d₁d₂d₃d₄d₅ can be extracted by de-correlation.

For cases where n>5, it is useful to point out that the value in de-correlating for all the coefficients in the multinomial expansion for extraction of \hat{d}ᵢ is relatively small. This is because the ρᵢ factor decreases rapidly for i∉{1,n} when n>5. An example of this is the case n=7. Then the Go-CDMA coded signal is:

$$\begin{matrix}s ( t ) = \frac{5}{16} {\sum }_{i = 1}^{7} {d}_{i} {X}_{i} ( t ) - \frac{1}{16} {\sum }_{i = 1}^{7} {\sum }_{j = i + 1}^{7} {\sum }_{k = j + 1}^{7} {d}_{i} {d}_{j} {d}_{k} {X}_{i} ( t ) {X}_{j} ( t ) {X}_{k} ( t ) + \\ \frac{1}{16} {\sum }_{i = 1}^{7} {\sum }_{j = i + 1}^{7} {\sum }_{k = j + 1}^{7} {\sum }_{l = k + l}^{7} {\sum }_{m = l + 1}^{7} {d}_{i} {d}_{j} {d}_{k} {d}_{l} {d}_{m} {X}_{i} ( t ) {X}_{j} ( t ) {X}_{k} ( t ) \\ {X}_{l} ( t ) {X}_{m} ( t ) - \frac{5}{16} {d}_{1} {d}_{2} {d}_{3} {d}_{4} {d}_{5} {d}_{6} {d}_{7} {X}_{1} ( t ) {X}_{2} ( t ) {X}_{3} ( t ) \\ {X}_{4} ( t ) {X}_{5} ( t ) {X}_{6} ( t ) {X}_{7} ( t )\end{matrix} \qquad \text{(1.26)}$$

Here, the value of ρᵢ when i∈{2,n−1}, is very small. Moreover, the desired orthogonality of the functions involved does not hold except perhaps approximately, so making any extraction imprecise.

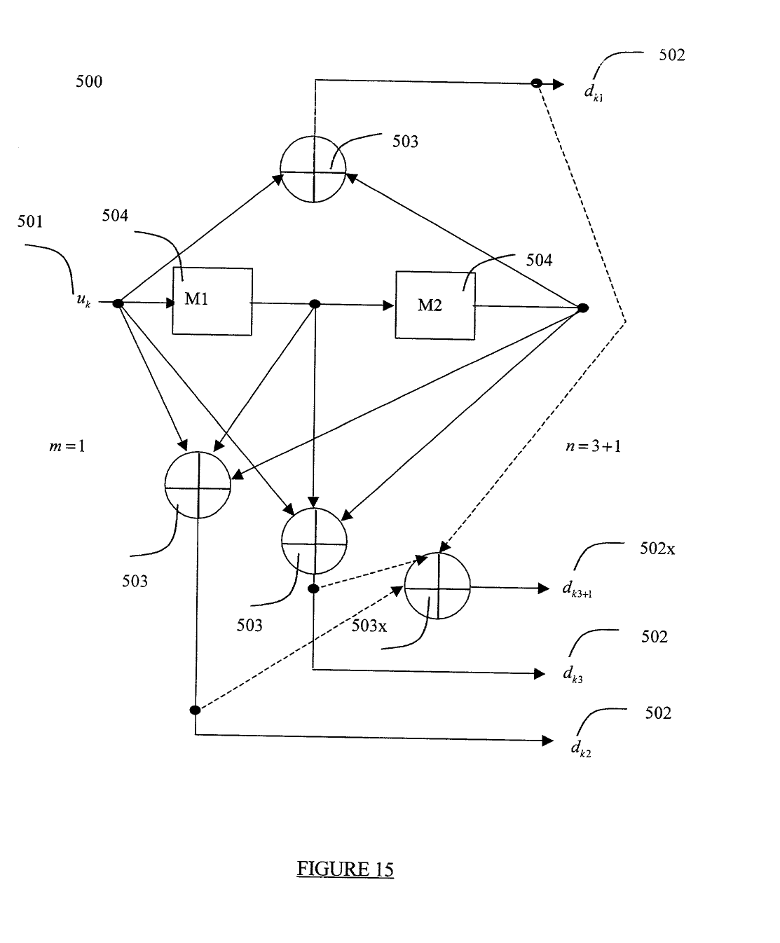

Of course, the sub-optimal detection scheme of (1.8)-(1.10) can be used for other cases of n. From FIG. 14, where the values of co-efficient ρ₁ are plotted against values of n, where n is odd, we can observe that at the very extreme, 10% of the signal amplitude (corresponding to 1% of signal power) can still be extracted from both the first non-zero term and last term of (1.5), when n≈65. For practical reasons, one may only use n≦9 with the sub-optimal detection scheme of (1.8)-(1.10), where a signal power of about 10% can be extracted, at most.

III. Multistage Coding with a Go-CDMA Coding Stage

As noted in the above section, Go-CDMA decoding can provide not only an estimate of the information bits d₁, d₂, . . . , d_{n∈{+}1,−1}, which are Go-CDMA coded, but also an estimate of the parity bit dₙ₋₁:=d₁d₂ . . . dₙ∈{+1,−1}. The soft estimation of these bits, denoted \hat{d}₁, \hat{d}₂, . . . , \hat{d}ₙ₊₁, may then be exploited in any subsequent decoding. The key to this is to view the Go-CDMA coder as driven by these n+1 bits, and in Go-CDMA decoding these bits are estimated. Any prior coding to achieve the n information bits is modeled as being augmented to generate the additional parity bit so together generates n+1 bits. In the decoding then of estimates of these n+1 bits, the decoding is of the augmented coder. This is presented in the following examples of coding using various coding techniques followed by Go-CDMA coding.

a) Two-Stage Convolution/Go-CDMA Coding.

Consider a standard, perhaps optimal,

$$\frac{m}{n}$$

rate convolution coder with M shift registers. The coder is then a discrete-time finite-memory dynamical system or finite-state machine, with m bipolar inputs, denoted uₖ, M bipolar states, denoted xₖ, and n bipolar outputs, denoted dₖ. Here k=0,1,2, . . . is a discrete time index. An equivalent coder works with unipolar signals in the set {0,+1}. For simplicity, we can focus on the special single input case when m=1, so that the input is a bipolar data stream, and the n outputs are an n-vector stream of bipolar coded data, with elements (dₖ₁, dₖ₂, . . . , dₖₙ)∈{+1,−1}. For this case, we give equations for the coder as

$${x}_{k} = {Ax}_{k - 1} + {Bu}_{k} ; {x}_{0} = 0 , \\ {d}_{kj} {\vert}_{j ∈ \{ 1 , 2 , 3 , … , n \}} = {\prod }_{i = 1}^{n} {g}_{i}^{T} {x}_{k} . \qquad \text{(1.27)}$$

Here,

$${x}_{k} = [ \begin{matrix}{u}_{k} \\ {u}_{k - 1} \\ {u}_{k - 3} \\ ⋮ \\ {u}_{k - M}\end{matrix} ] ; A = [ \begin{matrix}0 & 0 & ⋯ & 0 & 0 \\ 1 & 0 & ⋯ & 0 & 0 \\ 0 & 1 & ⋯ & ⋮ & ⋮ \\ ⋮ & ⋮ & ⋯ & 0 & 0 \\ 0 & 0 & ⋯ & 1 & 0\end{matrix} ] ; B = [ \begin{matrix}1 \\ 0 \\ 0 \\ ⋮ \\ 0\end{matrix} ] ; {G}^{T} = [ {g}_{1} {g}_{2} … {g}_{n} ] . \qquad \text{(1.28)}$$

and the gᵢ|_{I∈{1,2,3, . . . n}} are column n-vectors with bipolar elements. (If uₖ and the elements of G are unipolar, then so is xₖ, and dₖ, which is now given as

$${{d}_{kj} {\vert}_{j ∈ \{ 1 , 2 , 3 , … , n \}} = {\sum [}_{i = 1}^{n} {g}_{i}^{T} {x}_{k} ]}_{2} ,$$

where the [.]₂ indicates that any additions are modulo-2 additions.)

We now augment this coder to be an

$$\frac{m}{n + 1}$$

rate coder having outputs (dₖ₁, dₖ₂, . . . , dₖ₍ₙ₊₁₎)∈{+1,−1}, where dₖ₍ₙ₊₁₎=dₖ₁dₖ₂ . . . dₖₙ. The matrix G^{T} in (1.28) is merely augmented by an additional column gₙ₊₁ with each element g_{1+1,i} being a “parity check” of the elements above in that g_{n+1,i}=g_{1,i}g_{2,i} . . . g_{n,i}.

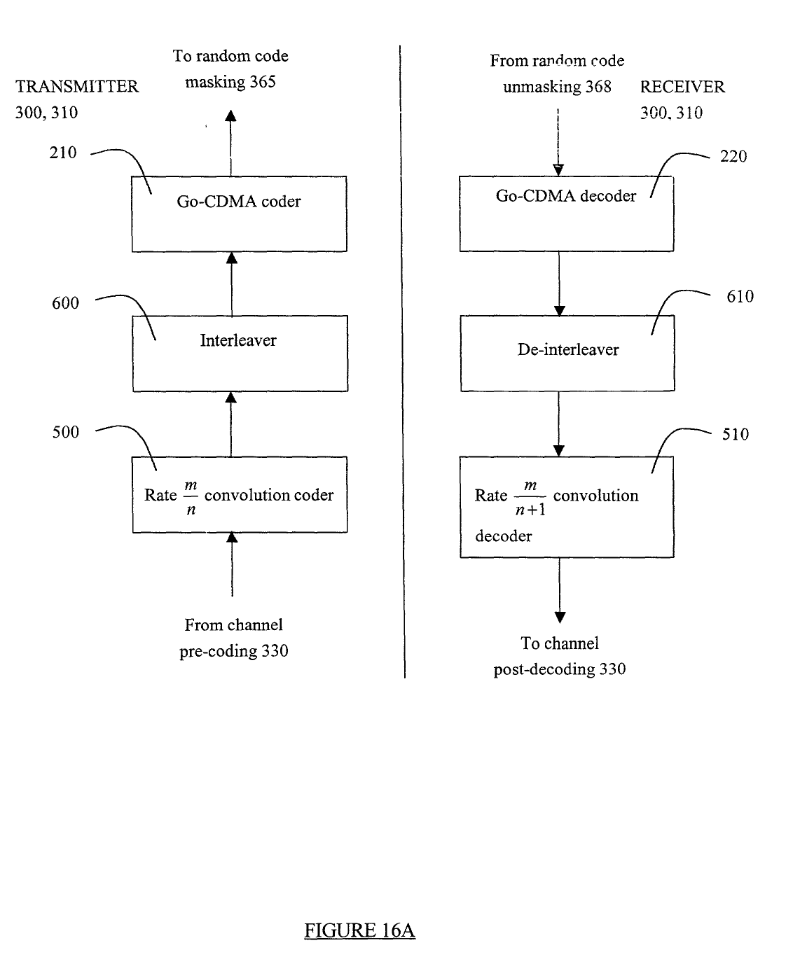

A simple example to illustrate this is given in FIG. 15, where a

$$\frac{1}{3}$$

rate convolution coder with two shift registers is indicated with full lines, and is augmented with dotted lines to be a

$$\frac{1}{4}$$

convolution coder, so that m=1, M=2, n=3. The

$$\frac{1}{3}$$

convolution coder as depicted in FIG. 15, but without the convolution output bit 502x, codes a single stream of information bits, which are in the binary form {0,+1}, to produce a 3-vector convolution coded binary bit stream 502, denoted dₖ₁, dₖ₂ and dₖ₃. These can then be augmented with dₖ₄=dₖ₁⊕dₖ₂⊕dₖ₃ as depicted in 502x, where ⊕ is the modulo-2 addition operation, to form the

$$\frac{1}{4}$$

rate convolution coder. The bit streams dₖ₁, dₖ₂ and dₖ₃, (ignoring d₄), are then interleaved (in process 600) in symbol blocks of {d₁, d₂, d₃}. These are then converted into bipolar binary form via a mapping of {0→+1,+1 →−1}. These bipolar coded bits are then coded using the Go-CDMA coding process 210 to generate the number of spreading bits in accordance with the required channel spreading factor. A random scrambling masking code 365 is then applied.

At the receiver, after random masking code unscrambling 368, and prior to de-interleaving 610, an estimated value of d₄, denoted \hat{d}₄, 502x, can be recovered. This is the contribution of an embodiment of Go-CDMA decoding, which exploits the last term in (1.5). At the receiver, the Go-CDMA decoded signal may be decoded using a soft decision. The decoded signal is then converted into binary form via a mapping of {+1→0,−1→+1}. The de-interleaved data may be fed into a soft decision Viterbi convolution decoding for the

$$\frac{1}{4}$$

convolution coder.

FIG. 15 only depicts a simple example of an embodiment of this invention. Other embodiments may have different values for m and n, with different numbers of delay shift registers M, 504 and different tap delay connections into each convolution process 503.

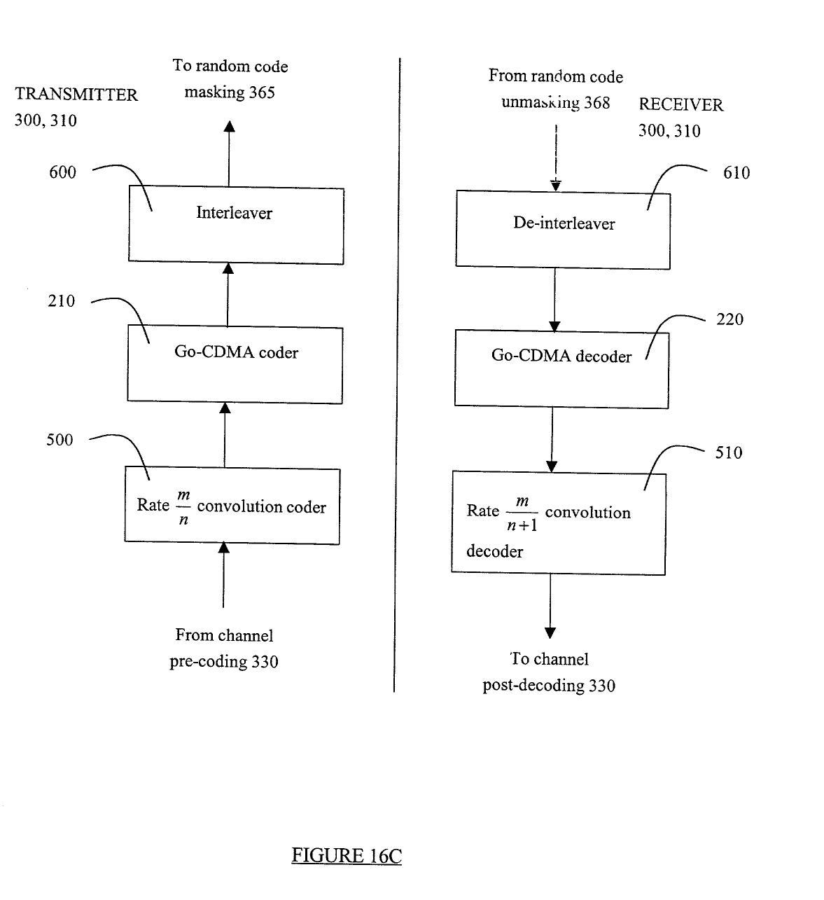

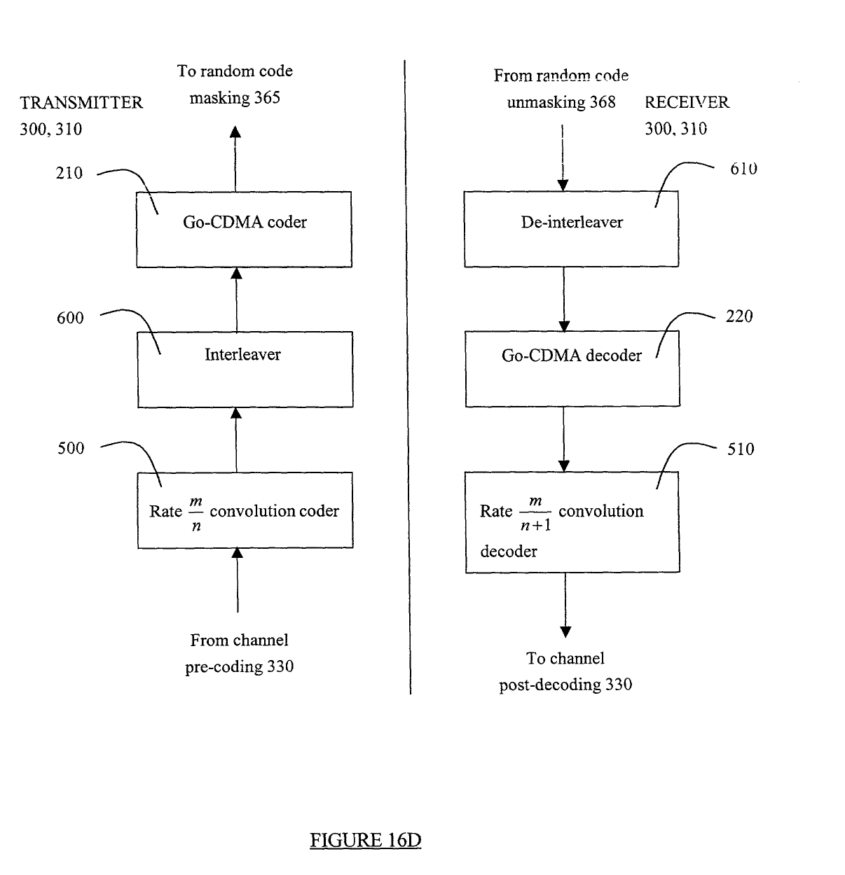

FIG. 16A depicts a simple block diagram of an overall architecture incorporating a convolution coder 500 and a decoder 510, a Go-CDMA coder 210 and a decoder 220, an interleaver 600 and a de-interleaver 610 before the random code masking 365 and de-masking 368 in a transceiver system in both 300 and 310. FIGS. 16B-16D depict other variations to the overall architecture of this embodiment.

The use of any block coding such as Go-CDMA coding following on from convolution coding is necessary to permit ‘RAKE symbol-detection’ receiver architectures to be used to detect convolution coded sequences without further signature spreading. The inability of pure convolution coding to permit signature detection on the coded bits is the Achilles heel in using pure convolution coding for channel spreading in a spread-spectrum system. In using Go-CDMA coding augmenting a convolution process, to permit the use of ‘RAKE symbol-detection’ receiver architectures, there is the advantage that the rate of the preceding convolution coding

$$\frac{m}{n}$$

is enhanced to

$$\frac{m}{n + 1} ,$$

and there is a corresponding performance enhancement. There is an effective loss of some signal energy using Go-CDMA coding, but this loss is partially offset by using the parity bit estimation of the enhanced Go-CDMA decoding.

Even in the case of not utilizing the parity bit estimation for better convolution coding gain, it is still an embodiment of the invention that the use of convolution coding together with Go-CDMA coding allows for the use of ‘RAKE symbol-detection’ receiver architectures, where otherwise it is not possible and the use of Go-CDMA coding for more robust noise immunity and better peak to average power (PAP) signal characteristics.

A Basic Implementation

A basic implementation of an embodiment of the present invention for wireless applications such as 3G and 3G+ applications, is a system at the transmitter, using a convolution coder with parameters in the ranges m∈{1,2,3,4,5,6,7,8}, n≦9, M∈{3,4,5,6,7,8,9, . . . M_{MAX}}, where M_{MAX} is the maximum number of shift registers supportable by the technology of the day. As for the Go-CDMA coder, the parameter n is in the range n≦9, and l set as the desired spreading factor of the spread spectrum system, such as 4 chips for data rates of 1 Mbps in the current 3G standard. Preferred values of n are the odd values {3,5,7,9}. The interleaver should be of sufficient size to handle the burst errors expected in the transmission channel. At the receiver, a compatible de-interleaver would be used after the soft decision Go-CDMA decoding. A convolution interleaver is a preferred choice for use with the convolution coding embodiment. The output of the de-interleaver may then be processed by a soft decision Viterbi convolution decoding process, using a decoding depth of at least 6 times the length of the delay taps at the convolution coder.

Other convolution code polynomial generator matrices G for the given constraint of gₙ₊₁ and for a code of rate

$$\frac{m}{n}$$

may be used. The performance measures for these code generators include the code free distance, optimal distance profile, optimal minimum distance and optimal spectrum profile. In a preferred basic implementation, an optimized G generator matrix is used. Nonetheless, “sub-optimal” convolution code polynomial generator matrices G may also be used according to embodiments of the present invention.

A Complex Implementation

In addition to the above basic implementation of the convolution coding embodiment, an example of a more complex, perhaps superior implementation is presented below.

A complex embodiment for wireless applications such as 3G and 3G+ is a system at the transmitter that uses a convolution coder with parameters in the ranges m∈{1,2,3,4,5,6,7,8}, n≦9, M∈{3,4,5,6,7,8,9, . . . M_{MAX}}, where M_{MAX} is the maximum number of shift registers supportable by the technology of the day. As for the Go-CDMA coder, the parameter n is in the range n≦9, and l set to give the desired spreading factor of the spread spectrum system, such as 4 chips for data rates of 1 Mbps in the current 3G standard. Preferred values of n are the odd values {3,5,7,9}. The interleaver should be of sufficient size to handle the burst errors expected in the transmission channel. At the receiver, a compatible de-interleaver would be used after the soft decision Go-CDMA decoding. A convolution interleaver is the preferred choice for use with the present convolution coding based embodiment. The output of the de-interleaver may then processed by a soft decision Viterbi convolution decoding process, using a decoding depth of at least 6 times the length of the delay taps at the convolution coder.

Other convolution code polynomial generator matrices G for the given constraint of gₙ₋₁, for convolution code of rate

$$\frac{m}{n}$$

may be used within the context of a more complex implementation architecture. In the preferred complex implementation, such an optimized G generator matrix is used. Nonetheless, “sub-optimal” convolution code polynomial generator matrices G may be used according to embodiments of the present invention.

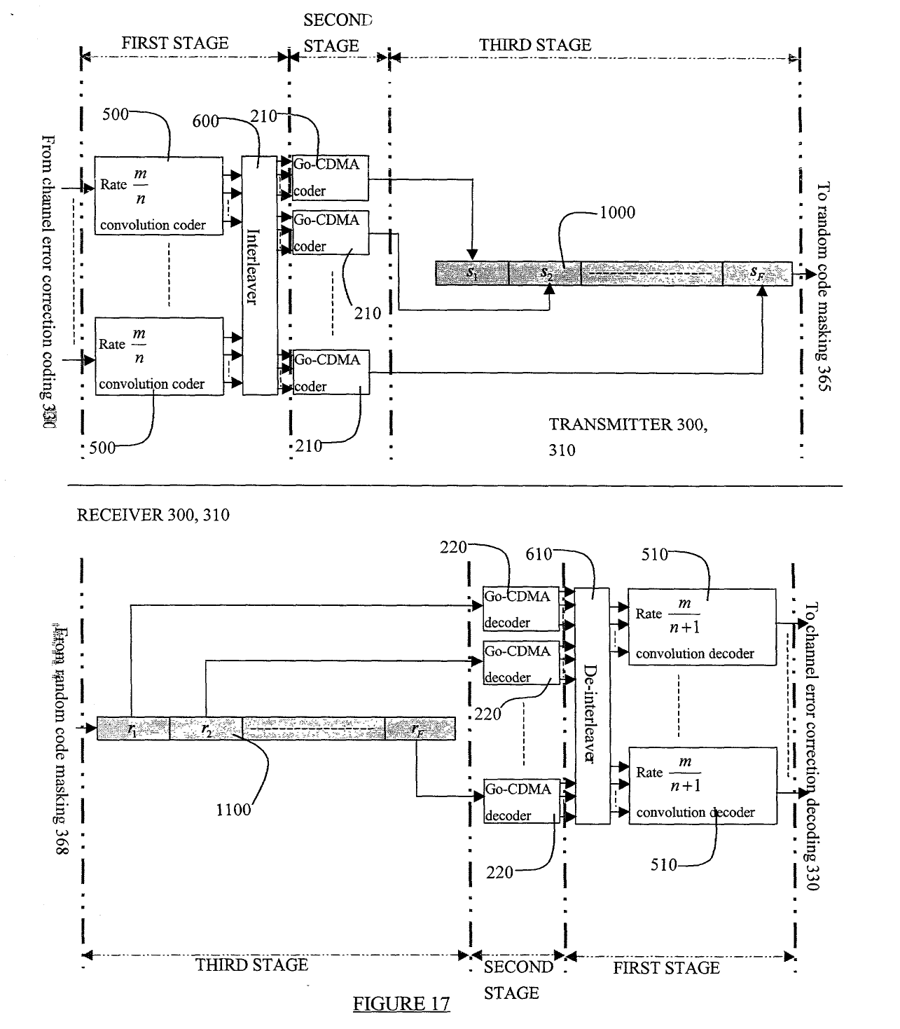

FIG. 17 depicts a block diagram of a more complex implementation that may be used to accomplish channel spreading. Referring to FIG. 17, the outputs of one or more standard convolution coderblock 500 with a coding rate of

$$\frac{m}{n} ,$$

are fed into two or more, Go-CDMA coder blocks 210, via an interleaver 600. The Go-CDMA code blocks perform Go-CDMA coding according to any Go-CDMA coding implementation and the outputs of the Go-CDMA coders are then concatenated temporally to form the transmitted sequence vector s (gray shaded area 1000 in FIG. 17), where

s=[s₁s₂ . . . s_{F}], (1.29)

and where F denotes the total number of Go-CDMA coders used. A random code mask 365 scrambles this sequence vector before transmission. The convolution coders 500 and the Go-CDMA coders 210 may be different from one another or the same.

At the receiver, after random code mask unscrambling in 368, the received sequence vector r (gray shaded area 1100 in FIG. 17), where

r=s+interferences=[r₁r₂ . . . r_{F}], (1.30)

is divided into sub-vectors of {r₁, r_{2, . . . r}_{F}}. These sub-vectors are then fed into Go-CDMA decoders 220, respectively. The outputs of these Go-CDMA decoders 220 are de-interleaved in block 610. Outputs of the de-interleaver 610 are then fed into the respective standard convolution decoder, where the Viterbi decoding algorithm is for an augmented convolution coder of rate

$$\frac{m}{n + 1} .$$

A channel post-decoding stage in 330 then further processes the outputs of these augmented convolution decoders.

For the more complex implementation, the spreading factor of the communications system is given as

$$Spreading Factor = \frac{{\sum }_{i = 1}^{F} length ( {s}_{i} )}{{\sum }_{j = 1}^{β} {m}_{j}} , \qquad \text{(1.31)}$$

where length (sᵢ) is a measure of the chip length of vector sᵢ and β=total number of rate

$$\frac{m}{n}$$

convolution coder used.

Note also the positioning of the interleaver and de-interleaver blocks follows the same variations as for the basic implementation diagrams depicted in FIG. 16A to FIG. 16D. In addition, when the coders 500 are different from one another and when the Go-CDMA coders 210 are different from one another, the corresponding differences are present in the receiver.

To further illustrate this more complex implementation, this implementation is presented as two different sub-categories, namely Non-Overlapped Complex (NOC) implementation and Overlapped Complex (OC) implementation.

Non-Overlapped Complex (NOC) Implementation

A Non-Overlapped Complex (NOC) implementation comprises of augmenting one or more standard convolution coding blocks with more than one Go-CDMA coding block.

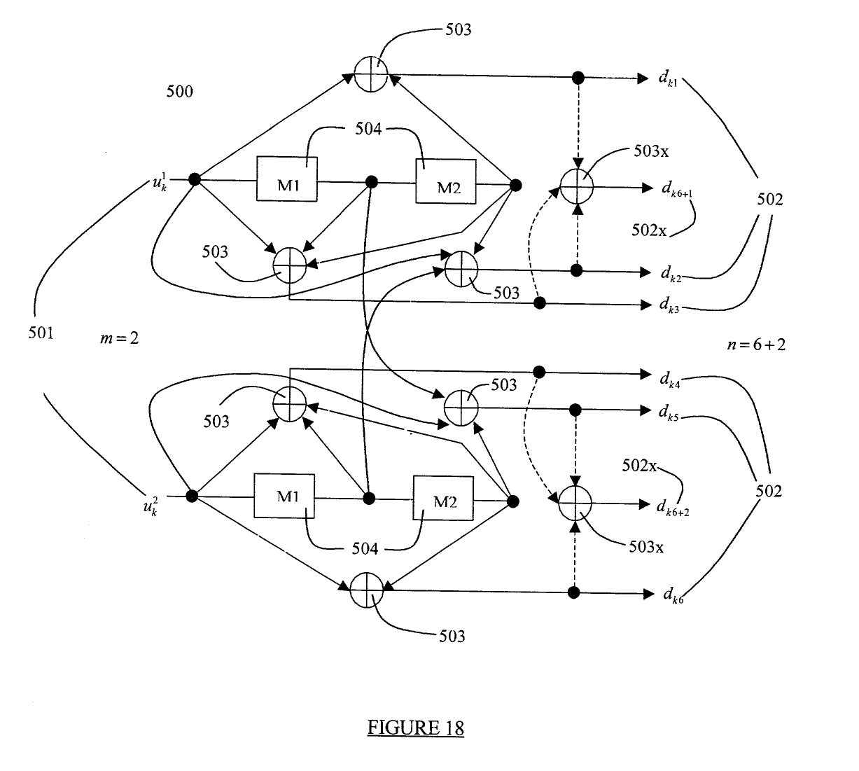

A simple example of the NOC implementation is given in FIG. 18, where a rate

$$\frac{2}{6}$$

convolution coder with four shift registers is indicted with full lines, and is augmented with dotted lines to be a

$$\frac{2}{8}$$

convolution coder, so that m=2, M=4, n=6. The

$$\frac{2}{6}$$

convolution coder as depicted in FIG. 18, but without the convolution output bits 502x, codes the input binary information bits, uₖ¹ and uₖ², which are in the binary form {0,+1}, to produce a 6-bit vector convolution coded binary stream 502, denoted dₖ₁, dₖ₂, dₖ₃, dₖ₄, dₖ₅ and dₖ₆. These can then be augmented with dₖ₆₋₁=dₖ₁⊕dₖ₂⊕dₖ₃ and dk₆₊₂=dₖ₄⊕dₖ₅⊕dₖ₆ as depicted in 502x, to form the

$$\frac{2}{8}$$

rate convolution coder. The bit streams dₖ₁, dₖ₂, dₖ₃, dₖ₄, dₖ₅ and dₖ₆, (ignoring dₖ₆₊₁ and dₖ₆₊₂), are then interleaved (in process 600) in symbol blocks of {dₖ₁, dₖ₂, dₖ₃} and {dₖ₄, dₖ₅, dₖ₆}. These are then converted into bipolar binary form via a mapping of {0→+1,+1→−1}. The bipolar coded bits are then coded using the Go-CDMA coding process 210 to generate the number of spreading bits in accordance with the required channel spreading factor. A random scrambling making code 365 is then applied.

At the receiver, after random masking code unscrambling 368, and prior to de-interleaving, an estimated value of dₖ₆₊₁ and dₖ₆₊₂, denoted \hat{d}ₖ₆₊₁ and \hat{d}ₖ₆₊₂, 502x, can be recovered. This is the contribution of the enhanced Go-CDMA decoding, which exploits the last term in (1.5). At the receiver, the Go-CDMA decoded signal is decoded using a soft decision, followed by a de-interleaving process. The de-interleaved data is fed into a soft decision Viterbi convolution decoding for the

$$\frac{2}{8}$$

convolution coder.

FIG. 18 only depicts a simple and illustrative example of an embodiment of this implementation. Other embodiments may have different values for m and n, with different number of delay shift registers M, 504, different tap delay connections into each convolution process 503, different combinations of convolution coded bits dₖᵢ, where i=1,2, . . . , n, to be coded by each Go-CDMA coder, different number of convolution coders 500 and decoder 510 and different numbers of Go-CDMA coders 210 and decoders 220. A distinguishing feature of the NOC implementation is that there is no overlap in the tap delay connects for the augmented bits recovered using the enhanced Go-CDMA decoding process. In other words, in the NOC implementation, each convolution coded bit dₖᵢ, where i=1,2, . . . , n, is only coded by one Go-CDMA coder.

Overlapped Complex (OC) Implementation

In the Overlapped Complex (OC) implementation, the same general structure depicted in FIG. 17 and FIG. 18 may still be used, but in the OC implementation, each convolution coded bit dₖᵢ, where i=1,2, . . . . n, can be coded by more than one Go-CDMA coder.

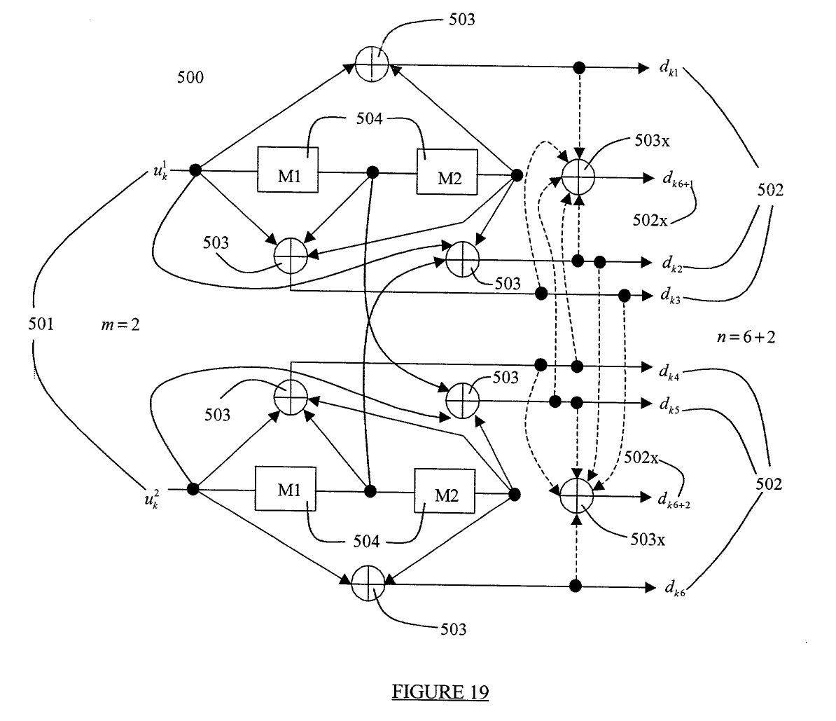

A simple example of the OC implementation is given in FIG. 19, where a rate

$$\frac{2}{6}$$

convolution coder with four shift registers is indicted with full lines, and is augmented with dotted lines to be a

$$\frac{2}{8}$$

convolution coder, so that m=2, M=4, n=6. The

$$\frac{2}{6}$$

convolution coder as depicted in FIG. 19, but without the convolution output bits 502x, codes the input binary information bits, uₖ¹ and uₖ², which are in the binary form {0,+1}, to produce a 6-bit vector convolution coded binary stream 502, denoted dₖ₁, dₖ₂, dₖ₃, dₖ₄, dₖ₅ and dₖ₆. These can then be augmented with dₖ₆₊₁=dₖ₁⊕dₖ₂⊕dₖ₃⊕dₖ₄⊕dₖ₅ and dₖ₆₊₂=dₖ₂⊕dₖ₃⊕dₖ₄⊕dₖ₅⊕dₖ₆ as depicted in 502x, to form the

$$\frac{2}{8}$$

rate convolution coder. The bit streams dₖ₁, dₖ₂, dₖ₃, dₖ₄, dₖ₅ and dₖ₆, (ignoring dₖ₆₊₁ and dₖ₆₊₂), are then interleaved (in process 600) in symbol blocks of {dₖ₁, dₖ₂, dₖ₃, dₖ₄, dₖ₅} and {dₖ₂, dₖ₃, dₖ₄, dₖ₅, dₖ₆}. These are then converted into bipolar binary form via a mapping of {0→+1,+1→−1}. The bipolar coded bits are then coded using the Go-CDMA coding process 210 to generate the number of spreading bits in accordance with the required channel spreading factor. A random scrambling making code 365 is then applied.

At the receiver, after random masking code unscrambling 368, and prior to de-interleaving, an estimated value of dₖ₆₊₁ and dₖ₆₊₂, denoted \hat{d}ₖ₆₊₁ and \hat{d}ₖ₆₊₂, 502x, can be recovered. This is the contribution of the enhanced Go-CDMA decoding, which exploits the last term in (1.5). At the receiver, the Go-CDMA decoded signal is decoded using a soft decision, followed by a de-interleaving process. The de-interleaved data is fed into a soft decision Viterbi convolution decoding for the

$$\frac{2}{8}$$

convolution coder.

FIG. 19 depicts a simple example of an embodiment of this implementation. Other embodiments may have different values for m and n, with different number of delay shift registers M, 504, different tap delay connections into each convolution process 503, different combinations, with overlapping, of convolution coded bits dₖᵢ, where i=1,2, . . . , n, to be coded by each Go-CDMA coder, different number of convolution coders 500 and decoder 510 and different numbers of Go-CDMA coders 210 and decoders 220. A distinguishing feature of the OC implementation is that there are some overlapping in the tap delay connections for the augmented bits recovered using the enhanced Go-CDMA decoding process. This means that in the OC implementation, each convolution coded bit dₖᵢ, where i=1,2, . . . , n, can be coded by more than one Go-CDMA coder.

Both the NOC and OC implementations allow for greater flexibilities in configuring different two-stage convolution/Go-CDMA coding schemes in order to achieve the best performance for given constraints in spreading factor, shift registers and data rates.

There exists a range of desirable (in terms of the code free distance, optimal distance profile, optimal minimum distance and optimal spectrum profile) convolution code polynomial generator matrices G for the given constraint of gₙ₊₁, for convolution code of rate

$$\frac{m}{n}$$

within the context of the complex implementation. In a preferred complex implementation, an optimized G generator matrix is used. Nonetheless, other “sub-optimal” convolution code polynomial generator matrices G may be used.

Other Variations

Other variations to the present embodiment may comprise:

1) Use of Repetition Coding for Lower Data Rate Support

Repetition coding is perhaps desirable when the information data rate is lower than the maximum information data rate supported. A repetition of the information bit can be implemented by sampling at a higher rate than the desired data rate, either at the information stage before input into convolution coder, or at the coded data stage at the output of the convolution coder. Alternatively, repetitions at the spreading chip stage, at the output of the Go-CDMA coding, can be used. The number of repetitions is chosen to attain a compatible spreading factor for the lower information data rate.

An example of this is for supporting information data rate of 512 kbps in the context of 3G WCDMA communication systems. The required spreading factor in this case is 8 chips. A natural implementation of the present embodiment is to use a rate

$$\frac{m}{n}$$

convolution coder, where m∈{1, 2,3,4,5,6,7,8} and n≦9, followed by Go-CDMA coding, where l∈{8,16,32,64,128,256}. One possible variation to the natural implementation is to use a rate

$$\frac{m}{n}$$

convolution coder, where m∈{1,2} and n=3, followed by Go-CDMA coding, where l=4 and a repetition coding rate of 2.

At the receiver, the same but inverse process is performed. Moreover, all the decoded signal energies from the repeated information bits are summed to attain an estimate of the transmitted information bit at the receiver.

2) To Replace the Standard Convolution Coding with Rate Compatible Punctured Convolution (RCPC) Coding for Lower Data Rate Support

Another possible variation to this embodiment is to replace standard convolution coding of the present embodiment with a rate compatible punctured convolution (RCPC) coding in order to support different information data rates for the same convolution coding hardware structure. This variation can also be complemented by use of repetition coding as described above. At the receiver, the same but inverse process (RCPC decoding) is performed on the received signal.

b) Two-Stage Turbo/Go-CDMA Coding

Consider a standard, perhaps optimal,

$$\frac{m}{{n}_{Turbo}}$$

rate Turbo coder, where n_{Turbo} is the number of coded output bits of the Turbo coder, with two parallel recursive systematic convolution (RSC) coders of rate

$$\frac{m}{n} ,$$

respectively. Each of the RSC coder has M shift registers and pseudo-random interleaving is applied onto the information bits prior to coding by the second RSC coder. This is as depicted in FIG. 7. The Turbo coder can also be viewed as a Parallel Concatenated Convolution (PCC) coder. Hence, each of the RSC coder in the Turbo coder is then a discrete-time finite-memory dynamical system or finite-state machine, with m bipolar inputs, denoted uₖ, M bipolar states, denoted xₖ, and n bipolar outputs, denoted dₖ^{ζ}, where ζ∈{1,2}, representing either the RSC Coder 1 or RSC Coder 2 in the Turbo coder. Here k=0,1,2, . . . is a discrete time index. The basic structure of the RSC coder is as depicted in FIG. 8. An equivalent coder works with unipolar signals in the set {0,+1}.

Due to the fact that each of the RSC coders in the Turbo coder can be represented by an equivalent convolution coder, it is then a further embodiment of this invention that a two-stage convolution/Go-CDMA coding can be applied to each of the two RSC coders in the Turbo coder. This will allow us to achieve the enhancements of a two-stage Turbo/Go-CDMA coding.

For simplicity, we focus on the special single input case when m=1, so that the input is a bipolar data stream, and the n outputs are an n -bit vector stream of bipolar coded data, with elements (dₖ₁^{ζ}, dₖ₂^{ζ}, dₖ₃^{ζ} . . . , dₖₙ^{ζ})∈{+1,−1}. For the Turbo coder, it is recommended that the same code be used for both of its the RSC coders. Moreover, for every RSC coder, there is an equivalent convolution coder. Based on these assumptions, without loss of generality, we can give equations for the RSC coder as given in (1.27) and (1.28), where

$${x}_{k} = {Ax}_{k - 1} + {Bu}_{k} ; {x}_{0} = 0 , {d}_{kj}^{ζ} {\vert}_{j ∈ \{ 1 , 2 , 3 , … , n \}} = {\prod }_{i = 1}^{n} {g}_{i}^{T} {x}_{k} . \qquad ( 1.32 )$$

Here,

$${x}_{k} = [ \begin{matrix}{u}_{k} \\ {u}_{k - 1} \\ {u}_{k - 3} \\ ⋮ \\ {u}_{k - M}\end{matrix} ] ; A = [ \begin{matrix}0 & 0 & ⋯ & 0 & 0 \\ 1 & 0 & ⋯ & 0 & 0 \\ 0 & 1 & . & ⋮ & ⋮ \\ ⋮ & ⋮ & ⋯ & 0 & 0 \\ 0 & 0 & ⋯ & 1 & 0\end{matrix} ] ; B = [ \begin{matrix}1 \\ 0 \\ 0 \\ ⋮ \\ 0\end{matrix} ] ; {G}^{T} = [ {g}_{1} {g}_{2} … {g}_{n} ] , \qquad ( 1.33 )$$

and the gᵢ|_{I∈{1,2,3, . .} . ,n} are column n-vectors with bipolar elements. (If uₖ and the elements of G are unipolar, then so is xₖ, and dₖ^{ζ}, which is now given as

$${d}_{kj}^{ζ} {\vert}_{j ∈ \{ 1 , 2 , 3 , … , n \}} = {\sum }_{i = 1}^{n} {[ {g}_{i}^{T} {x}_{k} ]}_{2} ,$$

, where the [.]₂ indicates that any additions are modulo-2 additions.) Hence, with a PCC configuration of the convolution coder in (1.32) and (1.33) we would arrive at a Turbo coder of rate

$$\frac{m}{2 n} .$$

As in each convolution coder there is the account of the systematic path in its RSC equivalent; thus, the PCC equivalent of the Turbo coder has two systematic paths rather than one as in standard Turbo coding. This transformation allows for the following benefits:

Transforming a Turbo coder structure into a PCC coder structure of two identical standard convolution coders. Therefore, now we can apply the Go-CDMA coding enhancements onto the respective convolution coder in the same manner as described in the above section entitled “Two-stage Convolution/Go-CDMA coding”.

Furthermore, within the PCC coder structure, there are two systematic paths compared to just one in the Turbo coder structure.

Towards this end, we now augment the convolution coder of (1.32) and (1.33) (through the use of Go-CDMA coding and improved decoding, as detailed in previous sections) to be a

$$\frac{m}{n + 1}$$

rate coder having outputs (dₖ₁^{ζ}, dₖ₂^{ζ}, . . . , dₖₙ₊₁₎^{ζ})∈{+1,−1}, where dₖ₍ₙ₊₁₎^{ζ}=dₖ₁^{ζ}dₖ₂^{ζ} . . . dₖ₍ₙ₎^{ζ}. The matrix G^{T} in (1.33) is merely augmented by an additional column gₙ₊₁ with each element g_{n+1,i} being a “parity check” of the elements above in that g_{n+1,i}=g_{1,i}g_{2,i} . . . g_{n,i}.

It is the intention of this embodiment of the present invention to apply all the embodiments in the above section entitled “Two-stage Convolution/Go-CDMA coding” to each of the convolution coder in the standard Turbo coding structure.

At the receiver, augmented “parity check bits” are derived from the improved Go-CDMA decoding. These “parity check bits” will be used to enhance the performance of the decoding algorithms in the Turbo decoder. Moreover, because the two-stage Turbo/Go-CDMA coding approach allows the transmission of two systematic paths, rather than the one systematic path of standard Turbo coding, we achieve a further improvement on the general coding strength of standard Turbo coding schemes.

c) Two-Stage Block/Go-CDMA Coding

Based on simulation studies and observations from (1.5), we conjecture that in Go-CDMA systems, in the cases where n is even, there is no performance penalty in increasing the number of multiple access channels (inputs to the coder), from n channels to n+1 channels. This conjecture and the Go-CDMA coding enhancement described in above sections are now used to construct two-stage block/Go-CDMA coding. The benefits are not expected to be as significant as in the convolution/Go-CDMA coding or Turbo/Go-CDMA coding case, and indeed the relative benefits are expected to diminish as the block size increases.

An embodiment of this invention is a two-stage block/Go-CDMA coding scheme for the case of n information bits, where n is even. The block code merely adds one 1 parity bit, termed the first parity bit, to achieve an odd number n+1 of bits. This odd number of bits is now applied to a Go-CDMA coding scheme. The addition of the one parity bit does not cause any material performance loss in the Go-CDMA coding of the other bits, since n is even, but the estimation of the parity bit permits improved estimation of the information bits.

The Go-CDMA coding stage uses the enhanced Go-CDMA detection, which estimates an additional parity bit for the coded n+1 bits, termed the second parity bit. The smaller is n, the greater the impact of the first and second parity bits. The value of n=2 gives the greatest gains, and more details for this case than the more general case are presented.

An embodiment of this invention is when the information bits are organized in b×n blocks (matrices D) with b a positive integer and n a positive even integer. Depending on the value of b, various linear block-coding options can be implemented on the information bits to achieve the first parity bits associated with each row of D to augment the information bit matrix D by a column, denoted p. A further augmentation of the second parity check to each row of [D p], being the product of the row elements for the case of bipolar elements, and the modulo-2 sum in the case of unipolar elements, augments [D p] by an additional column, denoted φ, as B=[D p φ]. The enhanced Go-CDMA decoding then estimates this matrix B. The optimum decoding process to estimate the original information bits is maximum likelihood detection. This is simple to implement for small n, b.

One example is when n=2, b=2. The information bits are processed in blocks of 4 bits. Designating these information bits as {d₁, d₂, d₃, d₄}, the added first parity bits as {p₁,p₂} and the second parity bits as {φ₁,φ₂, and representing them in the matrix format B, then the collective information and added parity bits would be

$$B = [ \begin{matrix}{d}_{1} & {d}_{2} & {p}_{1} & {φ}_{1} \\ {d}_{3} & {d}_{4} & {p}_{2} & {φ}_{2}\end{matrix} ] . \qquad ( 1.34 )$$

One implementation of a linear block coding on bipolar information bits would result in

p₁=d₁d₃d₄; p₂=d₁d₂d₃; (1.35)

and thus,

φ₁=p₁d₂d₁=d₂d₃d₄; φ₂=p₂d₃d₄=d₁d₂d₄. (1.36)

In this implementation, each of the parity bits is supporting one particular information bit dᵢ, where i={1,2,3,4}. In the case of uni-polar information bits d^{T}=[d₁ d₂ d₃ d₄], then

[d^{T}G]₂=≡d₁d₂d₃d₄p_{2φ}₂p₁φ₁]=:d_{aug}^{T}, (1.37)

where [.]₂ again denotes that additions are in modulo-2 arithmetic, and G is the generating matrix

$$G = [ \begin{matrix}1 & 0 & 0 & 0 & 1 & 1 & 1 & 0 \\ 0 & 1 & 0 & 0 & 1 & 1 & 0 & 1 \\ 0 & 0 & 1 & 0 & 1 & 0 & 1 & 1 \\ 0 & 0 & 0 & 1 & 0 & 1 & 1 & 1\end{matrix} ] . \qquad ( 1.38 )$$

In an optimum decoding option, the above example would use maximum likelihood detection, checking the received information bits \hat{B} against 2⁴ possible patterns for D and thus B. Other sub-optimal decoding algorithms of the above example would comprise of the standard use of hard decision based decoding as follows.

The hard decision based decoding would use the parity check matrix H and its corresponding syndrome table together with error patterns, which can be corrected.

For the above example, the corresponding parity check matrix H is

$$H = [ \begin{matrix}1 & 1 & 1 & 0 & 1 & 0 & 0 & 0 \\ 1 & 1 & 0 & 1 & 0 & 1 & 0 & 0 \\ 1 & 0 & 1 & 1 & 0 & 0 & 1 & 0 \\ 0 & 1 & 1 & 1 & 0 & 0 & 0 & 1\end{matrix} ] . \qquad ( 1.39 )$$

The syndrome table generated by the 2⁴ possible data and associated d_{aug}, from d_{aug}^{T}H^{T} is given below. Also, the corresponding error patterns for all possible one and some two information-bit errors, which can be corrected, are given.

$${[ \begin{matrix}0 & 0 & 0 & 0 \\ 1 & 1 & 1 & 0 \\ 1 & 1 & 0 & 1 \\ 1 & 0 & 1 & 1 \\ 0 & 1 & 1 & 1 \\ 1 & 0 & 0 & 0 \\ 0 & 1 & 0 & 0 \\ 0 & 0 & 1 & 0 \\ 0 & 0 & 0 & 1 \\ 0 & 0 & 1 & 1 \\ 0 & 1 & 0 & 1 \\ 1 & 0 & 0 & 1 \\ 0 & 1 & 1 & 0 \\ 1 & 0 & 1 & 0 \\ 1 & 1 & 0 & 0 \\ 1 & 1 & 1 & 1\end{matrix} ]}^{Syndrome} {[ \begin{matrix}0 & 0 & 0 & 0 & 0 & 0 & 0 & 0 \\ 1 & 0 & 0 & 0 & 0 & 0 & 0 & 0 \\ 0 & 1 & 0 & 0 & 0 & 0 & 0 & 0 \\ 0 & 0 & 1 & 0 & 0 & 0 & 0 & 0 \\ 0 & 0 & 0 & 1 & 0 & 0 & 0 & 0 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1 \\ 1 & 1 & 0 & 0 & 0 & 0 & 0 & 0 \\ 1 & 0 & 1 & 0 & 0 & 0 & 0 & 0 \\ 1 & 0 & 0 & 1 & 0 & 0 & 0 & 0 \\ 1 & 0 & 0 & 0 & 1 & 0 & 0 & 0 \\ 1 & 0 & 0 & 0 & 0 & 1 & 0 & 0 \\ 1 & 0 & 0 & 0 & 0 & 0 & 1 & 0 \\ 1 & 0 & 0 & 0 & 0 & 0 & 0 & 1\end{matrix} ]}^{Error pattern} . \qquad ( 1.40 )$$

Other Implementations

Other possible implementations of this invention include different ways of exploiting parity bits in the Go-CDMA coding system for enhanced error correction, yet without changing spreading factors of the Go-CDMA codes. Three possible examples of these are:

Example A: Consider the case where there are two information bits d₁ and d₂, and the first parity bit is p₁=d₁, and the second parity bit is φ₁=d₂. In this case, each parity bit is supporting one information bit.

Example B: Consider the case where there are 9 channels in a 9×l Go-CDMA system, encoding only 8 information bits, {d₁, . . . , d₈}, and 1 parity bit p₁, where p₁=d₁d₂d₃d₄. Thus, with the inherent multinomial structure of the Go-CDMA coded signal, the second parity bit φ₁=p₁d₁d₂ . . . d₈=d₅d₆d₇d₈. In this example, the first parity bit is supporting the first 4 information bits and the second parity bit is supporting the last 4 information bits.

Example C: Consider the case where there are 9 channels in a 9×l Go-CDMA system, encoding an 8×8 block of information bits D_{8×8}, and one parity vector p, where

$${D}_{8 \times 8} = [ \begin{matrix}{d}_{1} & {d}_{2} & {d}_{3} & {d}_{4} & {d}_{5} & {d}_{6} & {d}_{7} & {d}_{8} \\ {d}_{9} & {d}_{10} & {d}_{11} & {d}_{12} & {d}_{13} & {d}_{14} & {d}_{15} & {d}_{16} \\ {d}_{17} & {d}_{18} & {d}_{19} & {d}_{20} & {d}_{21} & {d}_{22} & {d}_{23} & {d}_{24} \\ {d}_{25} & {d}_{26} & {d}_{27} & {d}_{28} & {d}_{29} & {d}_{30} & {d}_{31} & {d}_{32} \\ {d}_{33} & {d}_{34} & {d}_{35} & {d}_{36} & {d}_{37} & {d}_{38} & {d}_{39} & {d}_{40} \\ {d}_{41} & {d}_{42} & {d}_{43} & {d}_{44} & {d}_{45} & {d}_{46} & {d}_{47} & {d}_{48} \\ {d}_{49} & {d}_{50} & {d}_{51} & {d}_{52} & {d}_{53} & {d}_{54} & {d}_{55} & {d}_{56} \\ {d}_{57} & {d}_{58} & {d}_{59} & {d}_{60} & {d}_{61} & {d}_{62} & {d}_{63} & {d}_{64}\end{matrix} ] , \\ p = [ \begin{matrix}{p}_{1} & {p}_{2} & {p}_{3} & {p}_{4} & {p}_{5} & {p}_{6} & {p}_{7} & {p}_{8}\end{matrix} ] . \qquad ( 1.41 )$$

Each parity bit is checking for a column in the information bits block D_{8×8}, i.e. p₁ is a parity bit checking for the information bits across the information bit column d₁, d₉, d₁₇, d₂₅, d₃₃, d₄₁, d₄₉ and d₅₇. The parity vector then augments the information block to form an 8×9 matrix block with column 9 being the parity vector p as [D_{8×8} p].

With this approach, a 2-dimension parity encoding scheme is implemented, where the first parity bit is checking across the vertical dimension of an 8×8 information bits matrix, and the second parity checking across the horizontal dimension of the [D_{8×8} p] matrix.

d) Two-Stage Convolution or Block/Multi Code Go-CDMA Coding

In this embodiment, the convolution or Turbo or block coding may be performed according to the above described embodiments.

Multi Code Go-CDMA (MC-Go-CDMA) coding refers to the use of Go-CDMA codes as “non-linear distortion tolerant” MC-CDMA codes as described in co-pending U.S. patent application entitled “Method and Apparatus for Non-Linear Code-Division Multiple Access Technology” filed on Oct. 5, 2001 and hereby incorporated by reference herein.

As described in the above referenced application, when Go-CDMA codes are used as spreading codes in a MC-CDMA structure, the resulting multi-level composite signal is more tolerant to non-linear distortions. Thus, the MC-Go-CDMA decoded signals are more reliable. Capitalizing on this added reliability, another embodiment of the present invention is presented here.

The above embodiments of convolution coding or block coding are to be used with MC-Go-CDMA coding at the transmitter. At the receiver, after detecting the received signal r(t), where r(t)=s(t)+interferences, an estimated parity bit \hat{d}ₙ₊₁ is derived by the by the following operation

$${\hat{d}}_{n + 1} = {\int }_{0}^{t} sign ( r ( t ) ) {X}_{1} ( τ ) {X}_{2} ( τ ) … {X}_{n} ( τ ) ⅆ τ or \\ {\hat{d}}_{n + 1} = {\int }_{0}^{t} {sgn}_{\pm } ( r ( t ) ) {X}_{1} ( τ ) {X}_{2} ( τ ) … {X}_{n} ( τ ) ⅆ τ . \qquad ( 1.42 )$$

Thus, in this embodiment of the present invention the resulting soft decoded data bits {\hat{d}₁,\hat{d}_{2, . . . ,}\hat{d}ₙ,\hat{d}ₙ₊₁} are further used in either the convolution decoding or Turbo decoding or block decoding as in the present embodiments.

Error-correction operations in both pre-coding and post-decoding stages may be combined, assimilated or replaced with the above described embodiments of Go-CDMA with error-correction coding.

e) Code Trellis Representations of the Linear Coding Schemes Introduced in this Patent

Linear, finite state coding schemes may be represented in the form of trellis codes. Thus, for completeness, we give the following code trellis representations of basic coding schemes proposed in this patent.

Two-Stage Convolutional/Go-CDMA Coding as Trellis Coding

Consider a standard, perhaps optimal,

$$\frac{m}{n}$$

rate convolution coder with M shift registers. The coder is then a discrete-time finite-memory dynamical system or finite-state machine, with m bipolar inputs, denoted uₖ, M bipolar states, denoted xₖ, and n bipolar outputs, denoted dₖ. Here k=0,1,2, . . . is a discrete time index. For simplicity, we focus on the special case when the n outputs form an n-vector stream of bipolar coded data, with elements (dₖ₁, dₖ₂, . . . , dₖₙ)∈{+1,−1}.

The n outputs are Go-CDMA encoded. Since there are 2ⁿ possible n-bit vector inputs to the Go-CDMA encoder, there are 2ⁿ possible output sequences. Thus Go-CDMA encoding is a mapping of an n -bit vector to an output sequence. This mapping may be viewed as a part of the modulation process. The convolution coder, which is a finite state coder, together with this mapping, constitute a special trellis encoder.

a) Optimization of the Trellis Code

Optimization of the trellis code involves joint optimization of the convolution code and the modulation (mapping). Traditionally, in the design of a trellis code, a good convolution code is picked, and the mapping is then optimized. However, with convolution/Go-CDMA encoding, the mapping is fixed by Go-CDMA encoding. Therefore, the optimization of the trellis code relies on the optimization of the convolution code.

b) Trellis Decoding

By viewing convolution/Go-CDMA coding as trellis coding, Go-CDMA decoding and convolution decoding can be replaced altogether with a single step of trellis decoding.

The received sequence in a signaling interval is passed through a bank of 2ⁿ filters. Each filter matches to one of the possible output sequences. The outputs of the filters are used to compute the branch metrics in the trellis. Decoding is performed with the Viterbi algorithm.

Although trellis decoding is possible, Go-CDMA decoding followed by convolution decoding may still be preferred in practice. With Go-CDMA decoding, only n+1 filters are required while with trellis decoding, 2ⁿ filters are required.

Two-Stage Turbo/Go-CDMA Coding as Trellis Coding

For Turbo/Go-CDMA coding, the basic code trellis representation as in the case for convolution coding is used, but in the context of a parallel concatenated convolution (PCC) coder.

Two-Stage Block/Go-CDMA Coding as Trellis Coding

For the Block/Go-CDMA coding scheme, a code trellis representation may be formed by considering a binary

$$\frac{m}{n}$$

linear block code with generator and parity check matrices, G and H, respectively. During each encoding interval, a message of m information bits is shifted into the encoder memory and encoded into a codeword of n code bits. The n code bits are formed and shifted onto the channel in n bit time. Therefore, the encoding span Γ is finite and consists of n+1 time instances, where

Γ=1,2, . . . ,N}. (1.43)

Hence, the binary

$$\frac{m}{n}$$

linear block code may be represented by an n-section trellis diagram over the time span Γ. Further, because the n outputs of the block code encoder are Go-CDMA encoded and since there are 2ⁿ possible n-bit vector inputs to the Go-CDMA encoder, therefore there are 2ⁿ possible output sequences. Thus, Go-CDMA encoding is a mapping of an n-bit vector to an output sequence. This mapping can be viewed as a part of the modulation process. The linear block coder, which is a finite state coder with a code trellis, together with this Go-CDMA mapping, also constitute a special trellis encoder.

a) Optimization of the Trellis Code

Optimization of the trellis code requires the joint optimization of the linear block code and the modulation (mapping). Traditionally, in the design of a trellis code, a good linear block code is picked, and the mapping is then optimized. However, with block/Go-CDMA encoding, the mapping is fixed by Go-CDMA encoding. Therefore, the optimization of the trellis code relies on the optimization of the linear block code.

b) Trellis Decoding

By viewing block/Go-CDMA coding as trellis coding, Go-CDMA decoding and block decoding can be replaced altogether with a single step of trellis decoding.

The received sequence in a signaling interval is passed through a bank of 2ⁿ filters. Each filter matches to one of the possible output sequences. The outputs of the filters are used to compute the branch metrics in the trellis. Decoding is performed with a maximum likelihood algorithm.

Although trellis decoding may be implemented, Go-CDMA decoding followed by block decoding may still be preferred in practice. With Go-CDMA decoding, n+1 filters are required while with trellis decoding, 2ⁿ filters are required.

f) Trellis Coded Modulation (TCM) for the Linear Coding Schemes Introduced in this Patent

The GO-CDMA coded output from the embodiments of the present invention may be further modulated using Trellis Coded Modulation (TCM) techniques based on a proposal by Ungerboeck in 1982. The use of TCM at the transmitter may give each embodiment of the present invention a coding gain of 3 to 6 dB. Conventionally, such coding gains have only be achieved when corresponding TCM detection schemes, based on Maximum Likelihood Detection (MLD), are used at the receiver. MLD schemes have implementation complexities that increase exponentially with the number of possible signal patterns to be detected. Thus, the number of possible signal patterns in the output and the hardware technology of the day have limited practical implementations of TCM to small systems with a limited number of channels.

According to another embodiment of the present invention, conventional TCM schemes may be used to map the outputs of enhanced coding schemes according to the present invention.

TCM Mapping Using Non-Linear Block Code Word Matrices

One embodiment of the present invention is to map the transmitter outputs from the enhanced coding schemes according to the present invention to non-linear code word matrices using a TCM technique. The non-linear code word matrices may be constructed by the following means:

The Levenshtein's construction methodology;

The |u|u⊕v| construction methodology; and

The |u|u⊕v| construction methodology, where u and v are non-overlapping parts of the Go-CDMA coded output.

The receiver of this embodiment uses maximum likelihood detection techniques to estimate the received coded bits and the additional parity bit, or bits, which is then used in the augmented error decoding process of the present invention. Alternatively, the MLD process at the receiver can be extended to provide a maximum likelihood estimate of the transmitted data signal prior to error correction coding.

Practical Coding Implementations

In FIG. 17, the embodiments of channel spreading and subsequent coding according to the present invention are depicted in three stages for a possible practical implementation. Descriptions on possible practical implementations are presented in this section.

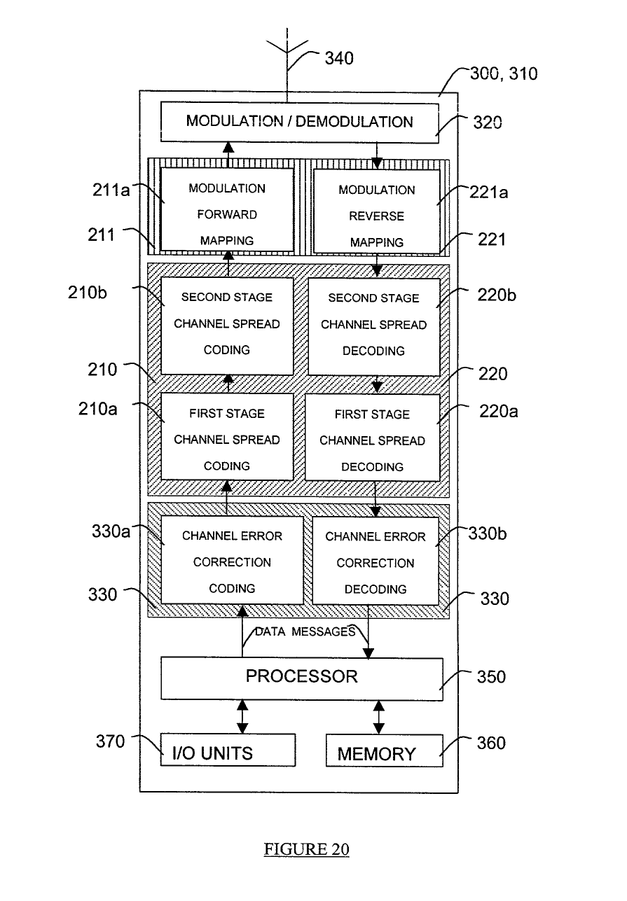

FIG. 20 depicts a functional block diagram encompassing the channel error correction coding & decoding (330a & 330b), channel spreading & dispreading (210 & 220) and modulation forward & reverse mapping (211 & 221) of a communications system pertinent to the practical coding implementation of the present invention. Each horizontal layer of the system as shown, between the antenna and the channel error correction coding and decoding block 330, including the block 330 itself, may be considered a distinct coding stage.

One practical implementation for the embodiments of the present invention is communication systems as depicted in FIG. 20, where the channel spreading & dispreading (210 & 220) functional block comprises two coding stages. The first coding & decoding stage (210a & 220a) primarily has the function of providing error correction coding while the second coding & decoding stage (210b & 220b) has both the functions of further strengthening the error correction coding of the first stage (210a & 220a) and channel spreading for the communication system. As depicted in FIG. 20, the output from the second stage coding 210b of the channel spreading functional block optionally can be further mapped via trellis coded modulation techniques prior to channel modulation in 320. The reverse processes are also optionally applicable at the receiving end.

Another practical implementation for the embodiments of the present invention is a communication system similar to the system depicted in FIG. 20 where the channel error correction coding & decoding (330a & 330b) functional blocks have each respectively been combined with the first stage coding & decoding (210a & 220a) blocks to form a stronger error correction coding block. In this practical implementation, the modulation forward & reverse mapping (211 & 221) is also optional in the system.

For both practical implementations of the present invention, the output from the second stage coding 210b has a definite de-correlatable signal pattern. At the receiver, the de-correlatable signal pattern may be decorrelated by mathematical techniques described herein that grow linearly in complexity with the number of data channels.

While specific embodiments of the present invention have been disclosed, it will be understood by those having ordinary skill in the art that changes may be made to those embodiments without departing from the spirit and scope of the invention. For example, while various functions and coding stages have been described, it will be understood that one or more stages may be combined into a single functional block and conversely that a single functional block may be broken into one ore more stages. Any implementation of the functions and techniques described herein are within the scope of the invention, regardless of which stage the function or technique is implemented in or how many stages the function or technique is implemented in. It will be further understood that the mathematical and matrix operations using Go-CDMA codes and matrices, with error-correction coding, may be implemented in hardware or software. In the latter case, software instructions and data may be embodied in a computer useable medium and stored in a memory of a communications device. The software instructions may include control logic which when executed by a processor or other hardware cause the communications device to encode and decode data messages based on the Go-CDMA codes, with error correction coding as depicted in the Figures described herein. When implemented in hardware or firmware, the mathematical and matrix operations using Go-CDMA codes and matrices, with error-correction coding, may be provided by logic on one or more chips or may be burned into, for example, an EEPROM as program instructions and data. It will be further understood that the Go-CDMA codes and matrices, with error-correction, may, for retrieval and use by a system, be stored in a memory, embodied in hardware, received from an external source such as other hardware or memory, or derived or generated from stored data or hardware internal to or external to the system.

What is claimed is:

1. A method of coding data signals for transmission, comprising:
in a first coding stage, generating coded bits based on a data signal using an error correction coding scheme;
in a second stage, further coding the coded bits based on a non-linear block error correction coding scheme to achieve an output having a detectable pattern; and
transmitting a channel spread signal based on the output.

2. The method according to claim 1, wherein the first and second stage coding schemes are selected for enhanced error correction in a decoding process.

3. The method according to claim 1, wherein the second stage non-linear block error correction coding involves a Go-CDMA matrix multiplication operation.

4. The method according to claim 1, wherein the first stage error correction coding scheme is a convolution coding scheme.

5. The method according to claim 1, wherein the first stage error correction coding scheme is a Turbo coding scheme.

6. The method according to claim 1, wherein the first stage error correction coding scheme is a block coding scheme.

7. The method according to claim 1, further comprising interleaving the coding bits prior to the second stage of coding.

8. The method according to claim 1, further comprising interleaving the output prior to the transmitting.

9. The method according to claim 1, wherein the first stage includes at least one coder.

10. The method according to claim 1, wherein the second stage includes at least one non-linear block error coder.

11. A method according to claim 1, wherein coding of data for channel error correction objectives is included in the first stage channel-spreading coding.

12. The method according to claim 1, wherein the first and second coding stages are represented by a trellis coding scheme.

13. The method according to claim 1, wherein the output is modulated by a trellis coded modulation technique.

14. The method according to claim 1, wherein the output is mapped to non-linear code word matrices of greater code distances by a trellis coded modulation technique.

15. A method of decoding a channel spread encoded signal, comprising:
receiving a channel spread signal;
in a first decoding stage, decorrelating the received signal based on a non-linear error correction coding scheme to recover estimates of the coded bits, in blocks of n bits and estimating an additional parity bit or bits, from the received signal; and
in a second decoding stage, decoding the coded n bits and the additional parity bit or bits, based on an error correction decoding scheme to recover a data signal.

16. The method according to claim 15, wherein the channel spread signal is received and decorrelated in a multiple receiver structure, termed a RAKE receiver.

17. The method according to claim 16, wherein estimates of the data bits and parity bit or bits from each of RAKE receiver structures are soft values.

18. The method according to claim 16, wherein the first stage non-linear block error correction decoding involves a Go-CDMA matrix de-correlation operation.

19. The method according to claim 15, wherein the error correction decoding scheme is a convolution code decoding scheme.

20. The method according to claim 15, wherein the error correction decoding scheme is a Turbo code decoding scheme.

21. The method according to claim 15, wherein the error correction decoding scheme is a block code decoding scheme.

22. The method according to claim 15, further comp rising de-interleaving the received channel spread signal bits prior to the first stage of decoding.

23. The method according to claim 15, further comprising de-interleaving the bits after the first stage of decoding.

24. The method according to claim 15, wherein the channel spread signal is decoded in the first stage decoding by at least one non-linear block error decoder.

25. The method according to claim 15, wherein the second error correction decoding stage includes at least one decoder.

26. The method according to claims 15, wherein any decoding associated with channel error coding objectives, is integrated into the first decoding stage.

27. The method according to claim 16 wherein the first stage non-linear block error correction decoding involves a Go-CDMA matrix de-correlation operation.

28. The method according to claim 16, wherein the second stage decoder is a convolution code decoder.

29. The method according to claim 16, wherein the second stage decoder is a Turbo code decoder.

30. The method according to claim 16, wherein the second stage decoder is a block code decoder.

31. The method according to claim 16, further comprising de-interleaving the received channel spread signal bits prior to the first stage of decoding.

32. The method according to claim 16, further comprising de-interleaving the bits after the first stage of decoding.

33. The method according to claim 16, wherein the channel spread signal is decoded in the first stage decoder by at least one non-linear block error decoder.

34. The method according to claim 16, wherein the second decoding stage includes at least one decoder.

35. The method according to claim 16, wherein any decoding associated with channel error correction coding objectives, is integrated into the first decoding stage.

36. The method according to claim 15, wherein the decoding of a channel spread coded signal is based on maximum likelihood detection algorithm.

37. The method according to claim 16, wherein the decoding of a channel spread coded signal is based on maximum likelihood detection algorithm.

38. The method according to claim 35, wherein the decoding of a channel spread coded signal is based on maximum likelihood detection algorithm for a trellis decoding scheme.
